(19) United States
(12) Patent Application Publication
(10) Pub. No.: US 2007/0212797 A1
(43) Pub. Date: Sep. 13, 2007

(54) Method of forming a ferroelectric device

(76) Inventors: Suk-Hun Choi, Suwon-si (KR); Jang-Eun Heo, Seoul (KR); Yoon-Ho Son, Yongin-si (KR); Chang-Ki Hong, Seongnam-si (KR); Yong-Ju Jung, Hwaseong-si (KR); Hwa-Young Ko, Seoul (KR); Dong-Hyun Im, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/715,441

(22) Filed: Mar. 8, 2007

(30) Foreign Application Priority Data
Mar. 8, 2006 (KR) 2006-21729
Jun. 8, 2006 (KR) 2006-51414

(51) Int. Cl. H01L 21/00

(52) U.S. Cl. 438/3

(57) ABSTRACT

A method of forming a ferroelectric device includes forming a ferroelectric pattern on a substrate, the ferroelectric pattern including a ferroelectric material including titanium and oxygen, forming an insulating layer on the ferroelectric pattern, and planarizing the insulating layer using a slurry until the ferroelectric pattern is exposed, wherein the ferroelectric pattern serves as a polishing stop pattern and the slurry includes ceria.

### BACKGROUND OF THE INVENTION

1. Field of the Invention

The present invention relates to a method of forming a ferroelectric device. More particularly, the present invention relates to a method of forming a ferroelectric device that includes planarizing a layer using a ferroelectric material as a polishing stop.

2. Description of the Related Art

Generally, a CMP process is employed to planarize a layer, e.g., an insulating layer, which covers a polishing stop pattern. The layer to be planarized may have a polishing rate greater than that of the polishing stop pattern. A ferroelectric memory device may be manufactured using a ferroelectric pattern as a polishing stop pattern in the CMP process. However, when the ferroelectric pattern is used as the polishing stop pattern, a loss of the ferroelectric pattern may be relatively large because a polishing rate of the ferroelectric pattern in the CMP process may be relatively large. In addition, defects may be generated in the ferroelectric pattern by the CMP process.

### SUMMARY OF THE INVENTION

The present invention is therefore directed to a method of forming a ferroelectric device, which substantially overcomes one or more of the problems due to the limitations and disadvantages of the related art.

It is therefore a feature of an embodiment of the present invention to provide a method of forming a ferroelectric device that may reduce or eliminate damage to a ferroelectric pattern.

It is therefore another feature of an embodiment of the present invention to provide a method of forming a ferroelectric device wherein a layer formed on a ferroelectric pattern is planarized using the ferroelectric pattern as a polishing stop pattern.

It is therefore a further feature of an embodiment of the present invention to provide a method of forming a ferroelectric device wherein a slurry used to planarize a layer formed on a ferroelectric pattern has a relatively low polishing rate toward the ferroelectric pattern.

At least one of the above and other features and advantages of the present invention may be realized by providing a method of forming a ferroelectric device including forming a ferroelectric pattern on a substrate, the ferroelectric pattern including a ferroelectric material including titanium and oxygen, forming an insulating layer on the ferroelectric pattern, and planarizing the insulating layer using a slurry until the ferroelectric pattern is exposed, wherein the ferroelectric pattern serves as a polishing stop pattern and the slurry includes ceria.

The ferroelectric material may include at least one of PZT, SBT, BLT, PLZT, or BST. The slurry may have a pH of about 5 to about 9. The insulating layer may include at least one of boro-phosphor silicate glass, phosphor silicate glass, undoped silicate glass, spin-on-glass, flowable oxide, plasma-enhanced tetra-ethyl-ortho-silicate, high density plasma chemical vapor deposition oxide, silicon nitride, or silicon oxynitride. Planarizing the insulating layer may include a chemical mechanical polishing process.

The method may further include forming a lower electrode on the substrate, wherein the lower electrode may be between the substrate and the ferroelectric pattern, and forming an upper electrode on the ferroelectric pattern. The insulating layer may cover the ferroelectric pattern, exposing the ferroelectric pattern may transform the insulating layer into an insulating pattern, and the upper electrode may be formed on the ferroelectric pattern and the insulating pattern. The method may further include forming a transistor on the substrate, wherein the lower electrode may be electrically connected to a source/drain region of the transistor. The method may further include forming a curing pattern on the substrate, wherein the curing pattern may be between the ferroelectric pattern and the upper electrode, and the curing pattern may include strontium ruthenium oxide.

The method may further include forming a lower electrode layer on the substrate, forming a ferroelectric layer on the lower electrode layer, forming an adhesion layer on the ferroelectric layer, forming a mask pattern on the adhesion layer, and etching the adhesion layer, the ferroelectric layer and the lower electrode layer using the mask pattern as an etch mask so as to form an adhesion pattern, the ferroelectric pattern and a lower electrode. Planarizing the insulating layer may include planarizing the mask pattern and the adhesion pattern using the slurry. The method may further include forming an upper electrode on the ferroelectric pattern after planarizing the mask pattern, the adhesion pattern and the insulating layer.

Forming the adhesion layer may include forming an oxide using a source gas that contains hydrogen, and the hydrogen may deteriorate a surface of the ferroelectric layer. The oxide may be an aluminum oxide. The hydrogen contained in the source gas may be provided by trimethylaluminum. The method may further include removing the deteriorated surface after planarizing the insulating layer. Removing the deteriorated surface may include a chemical mechanical polishing process using a slurry that includes ceria. The slurry used in removing the deteriorated surface may have a pH of about 5 to about 9. Removing the deteriorated surface may include a chemical mechanical polishing process using a slurry that includes silica. Removing the deteriorated surface may include an etch-back process using an etching gas that includes fluorine. The adhesion layer may include a metal oxide having a perovskite structure. The metal oxide may be strontium ruthenium oxide or chromium ruthenium oxide. The adhesion layer may be formed without using a source gas that includes hydrogen. The adhesion layer may be formed by a physical vapor deposition process.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1-2 illustrate cross-sectional views of stages in a chemical mechanical polishing method in accordance with a first embodiment of the present invention;

FIGS. 3-8 illustrate cross-sectional views of stages in a method of manufacturing a ferroelectric capacitor in accordance with a second embodiment of the present invention;

FIGS. 9-15 illustrate cross-sectional views of stages in a method of manufacturing a ferroelectric capacitor in accordance with a third embodiment of the present invention;

FIGS. 16-19 illustrate cross-sectional views of stages in a method of manufacturing a ferroelectric capacitor in accordance with a fourth embodiment of the present invention;

FIGS. 20-23 illustrate cross-sectional views of stages in a method of manufacturing a ferroelectric capacitor in accordance with a fifth embodiment of the present invention;

FIGS. 24-29 illustrate cross-sectional views of stages in a method of manufacturing a ferroelectric capacitor in accordance with a sixth embodiment of the present invention;

FIGS. 30-39 illustrate cross-sectional views of stages in a method of manufacturing a ferroelectric memory device in accordance with a seventh embodiment of the present invention;

FIGS. 40-43 illustrate cross-sectional views of stages in a method of manufacturing a ferroelectric memory device in accordance with a eighth embodiment of the present invention;

FIGS. 44-47 illustrate cross-sectional views of stages in a method of manufacturing a ferroelectric memory device in accordance with an ninth embodiment of the present invention;

FIGS. 48-53 illustrate cross-sectional views of stages in a method of manufacturing a ferroelectric memory device in accordance with a tenth embodiment of the present invention;

FIG. 54 illustrates a graph of hysteresis loops of ferroelectric patterns measured in an experiment regarding a polarization of the ferroelectric patterns;

FIG. 55 illustrates a graph of leakage currents flowing through ferroelectric patterns measured in an experiment regarding a polarization of the ferroelectric patterns;

FIGS. 56-60 illustrate graphs of hysteresis loops of ferroelectric patterns measured in an experiment regarding an etch-back process; and

FIG. 61 illustrates a graph of a hysteresis loop of a ferroelectric layer measured in an experiment regarding a second adhesion layer including a metal oxide.

### DETAILED DESCRIPTION OF THE INVENTION

Korean Patent Application No. 10-2006-0021729, filed Mar. 8, 2006, and Korean Patent Application No. 10-2006-0051414, filed Jun., 8, 2006, in the Korean Intellectual Property Office, both of which are entitled: “Chemical Mechanical Polishing Method, Method of Manufacturing a Ferroelectric Capacitor by Using the Chemical Mechanical Polishing Method and Method of Manufacturing a Ferroelectric Memory Device by Using the Chemical Mechanical Polishing Method,” are incorporated by reference herein in their entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and “including” specify the presence of stated features, integers, steps, operations, elements, and/or components, but do not preclude the presence and/or addition of one or more other features, integers, steps, operations, elements, components, and/or groups thereof.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include a fourth member, whereas the expression “at least one selected from the group consisting of A, B, and C” does not.

As used herein, the expression “or” is not an “exclusive or” unless it is used in conjunction with the phrase “either.” For example, the expression “A, B, or C” includes A alone; B alone; C alone; both A and B together; both A and C together; both B and C together; and all three of A, B and, C together, whereas the expression “either A, B, or C” means one of A alone, B alone, and C alone, and does not mean any of both A and B together; both A and C together; both B and C together; and all three of A, B and C together.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention. Like reference numerals refer to like elements throughout.

### Chemical Mechanical Polishing Method

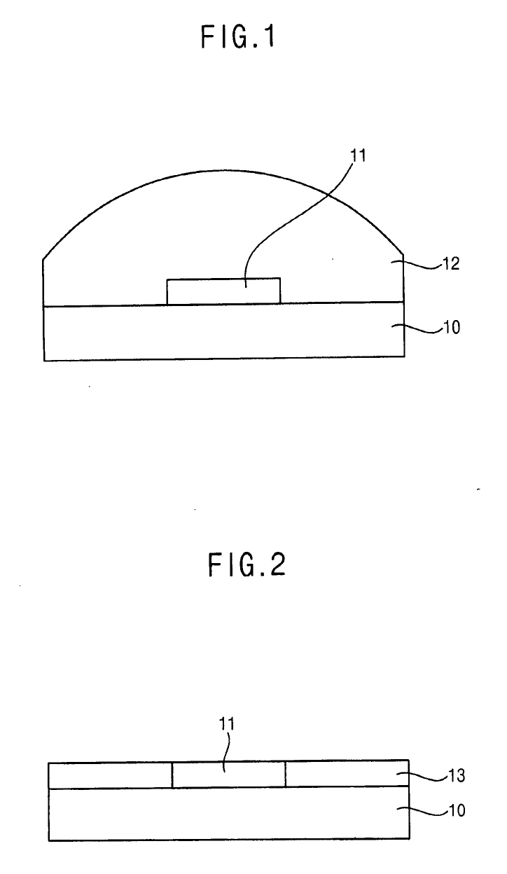

FIGS. 1-2 illustrate cross-sectional views of stages in a chemical mechanical polishing method in accordance with a first embodiment of the present invention. Referring to FIG. 1, a ferroelectric pattern 11 may be provided on a lower structure 10. The lower structure 10 may be, e.g., a substrate, and may include one or more layers. The ferroelectric pattern 11 may include a ferroelectric material including titanium and oxygen, e.g., one or more of PZT [Pb Zr, Ti O₃], SBT [SrBi₂Ti₂O₉], BLT [Bi La, Ti O₃], PLZT [Pb La, Zr TiO₃], BST [Bi Sr, Ti O₃], etc.

An insulating layer 12 may be formed on the lower structure 10 and may cover the ferroelectric pattern 11. The insulating layer 12 may include, e.g., oxide, nitride, oxynitride, etc. For example, the insulating layer 12 may include one or more of boro-phosphor silicate glass (BPSG), phosphor silicate glass (PSG), undoped silicate glass (USG), spin-on-glass (SOG), flowable oxide (FOX), plasma-enhanced tetra-ethyl-ortho-silicate (PE-TEOS), high density plasma chemical vapor deposition (HDP-CVD) oxide, silicon nitride, silicon oxynitride, etc.

Referring to FIG. 2, a CMP process may be performed to planarize the insulating layer 12. The insulating layer 12 may be removed until the ferroelectric pattern 11 is exposed. Thus, the insulating layer 12 shown in FIG. 1 may be transformed into an insulating pattern 13, as shown in FIG. 2.

A polishing slurry including ceria may be used in the CMP process. Where the slurry includes ceria, a polishing rate of the insulating layer 12 may be greater than that of the ferroelectric pattern 11 in the CMP process. Thus, it may be possible to use the ferroelectric pattern 11 as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 11. Using a pH of more than about 9 may also increase the polishing rate of the ferroelectric pattern 11. If the polishing rate of the ferroelectric pattern 11 in the slurry is unduly increased, it may not be effective to use the ferroelectric pattern 11 as a polishing stop pattern.

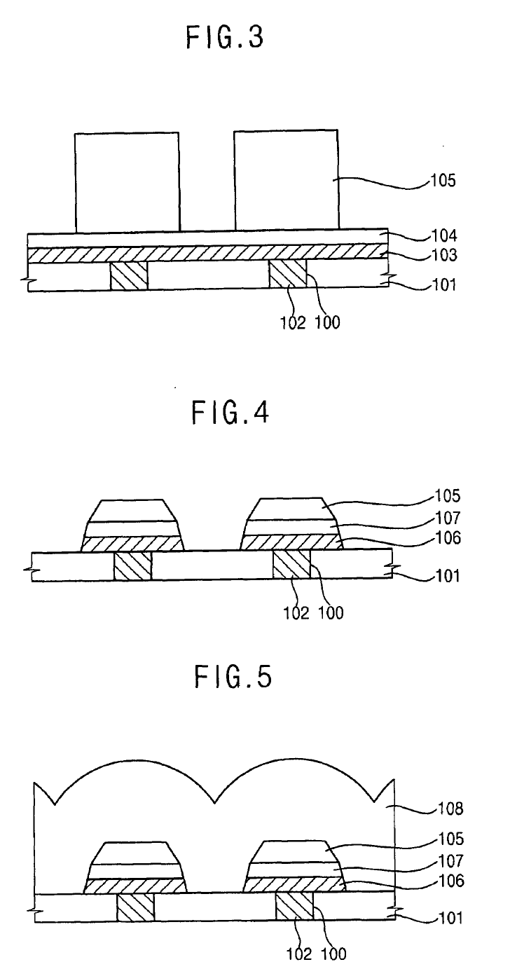

FIGS. 3-8 illustrate cross-sectional views of stages in a method of manufacturing a ferroelectric capacitor in accordance with a second embodiment of the present invention. Referring to FIG. 3, a first insulating pattern 101 having a hole 100 may be formed on an underlying structure (not shown), and a contact structure 102 may be formed in the hole 100. An upper face of the first insulating pattern 101 may be substantially coplanar with an upper face of the contact structure 102.

A lower electrode layer 103 and a ferroelectric layer 104 may be successively formed on the first insulating pattern 101 and the contact structure 102. The ferroelectric layer 104 may include a ferroelectric material including titanium and oxygen. For example, the ferroelectric material may include one or more of PZT, SBT, BLT, PLZT, BST, etc.

A mask pattern 105 may be formed on the ferroelectric layer 104. The mask pattern 105 may be disposed over the contact structure 102. A width of the mask pattern 105 may be greater than a width of the contact structure 102.

Referring to FIG. 4, the ferroelectric layer 104 and the lower electrode layer 104 may be successively etched using the mask pattern 105 as an etch mask. Thus, the ferroelectric layer 104 and the lower electrode layer 103 may be transformed into a ferroelectric pattern 107 and a lower electrode 106, respectively. A size of the mask pattern 105 may be reduced when the ferroelectric layer 104 and the lower electrode layer 103 are etched.

Referring to FIG. 5, a second insulating layer 108 may be formed on the first insulating pattern 101, and may cover the lower electrode 106, the ferroelectric pattern 107 and the mask pattern 105. The second insulating layer 108 may include, e.g., oxide, nitride, oxynitride, etc. For example, the second insulating layer 108 may include one or more of BPSG, PSG, USG, SOG, FOX, PE-TEOS, HDP-CVD oxide, silicon nitride, silicon oxynitride, etc.

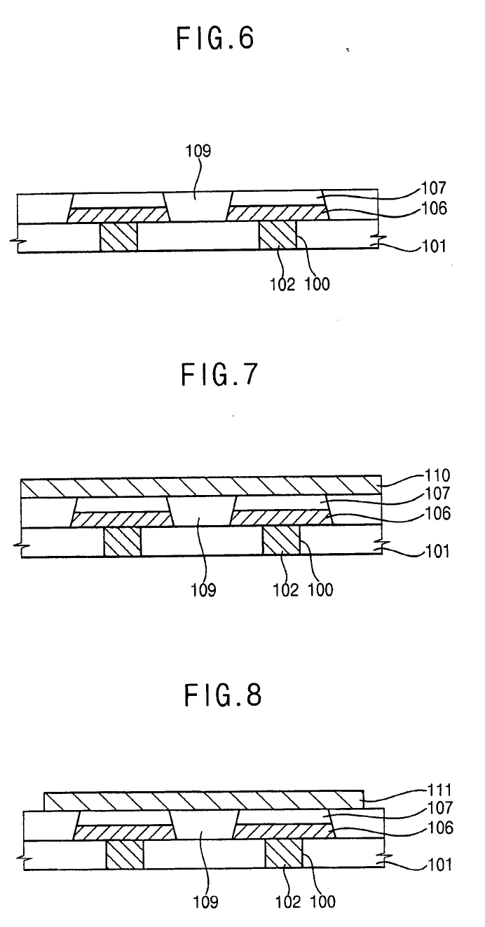

Referring to FIG. 6, a CMP process may be performed on the above-described structure. The CMP process may remove the second insulating layer 108 and the mask pattern 105 until the ferroelectric pattern 107 is exposed. Thus, the second insulating layer 108 may be transformed into a second insulating pattern 109. The mask pattern 105 may be removed by the CMP process.

A slurry including ceria may be used in the CMP process. Where the slurry includes ceria, a polishing rate of the second insulating layer 108 may be greater than that of the ferroelectric pattern 107 in the CMP process. Thus, it may be possible to use the ferroelectric pattern 108 as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 107. Using a pH of more than about 9 may also increase the polishing rate of the ferroelectric pattern 107. If the polishing rate of the ferroelectric pattern 107 in the slurry is unduly increased, it may not be effective to use the ferroelectric pattern 107 as a polishing stop pattern.

A surface of the ferroelectric pattern 107 may be slightly removed in the CMP process. Thus, a surface characteristic, e.g., roughness, of the ferroelectric pattern 107 may be improved. For example, the surface of the ferroelectric pattern 107 may become substantially smoothened after the CMP process.

Referring to FIG. 7, an upper electrode layer 110 may be formed on the ferroelectric pattern 107 and the second insulating pattern 109. The upper electrode layer 110 may include a conductive material, e.g., metal, polysilicon doped with impurities, conductive metal nitride, etc.

Referring to FIG. 8, the upper electrode layer 110 may be etched to form an upper electrode 111. In an implementation, the upper electrode 111 may be electrically connected to two or more ferroelectric patterns 107. Thus, a ferroelectric capacitor structure including the lower electrode 106, the ferroelectric pattern 107 and the upper electrode 111 may be formed.

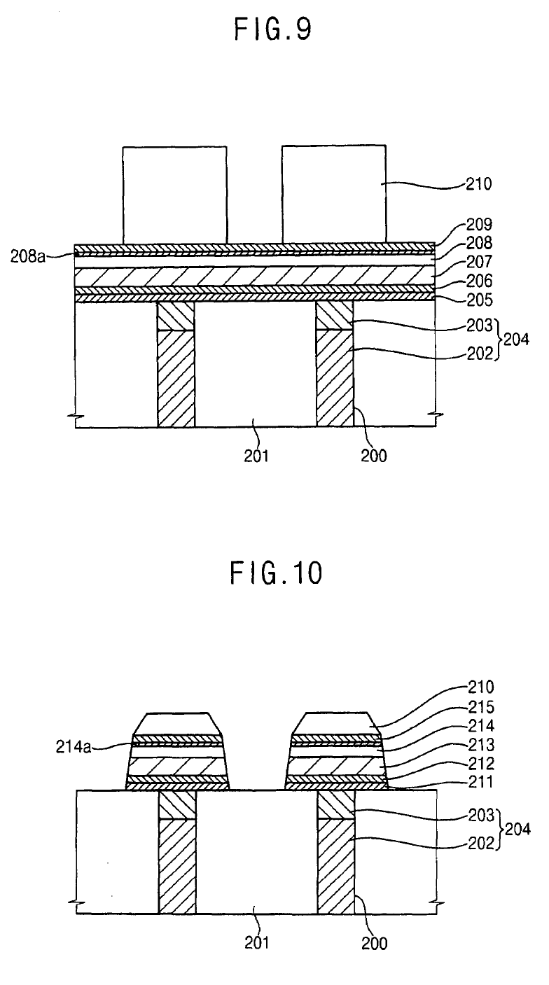

FIGS. 9-15 illustrate cross-sectional views of stages in a method of manufacturing a ferroelectric capacitor in accordance with a third embodiment of the present invention. Referring to FIG. 9, a first insulating pattern 201 having a hole 200 may be formed on an underlying structure (not shown), and a first conductive layer (not shown) may be formed in the hole 200. The first conductive layer may include, e.g., tungsten. The first conductive layer may be planarized until the first insulating pattern 201 is exposed, thereby forming a preliminary first contact (not shown) in the hole 200.

Where the preliminary first contact includes tungsten, dishing may occur at an upper portion of the preliminary first contact. Thus, a second contact 203 may be formed to prevent the dishing. In detail, an etch-back process may be performed on the preliminary first contact to remove an upper portion thereof, thereby transforming the preliminary first contact into a first contact 202. The first contact 202 may partially fill the hole 200. A second conductive layer (not shown) may be formed on the first insulating pattern 201 to fill up the hole 200 that is partially filled with the first contact 202. The second conductive layer may include, e.g., tungsten nitride. The second conductive layer may be planarized until the first insulating pattern 201 is exposed, thereby forming a second contact 203 that fills up the hole 200. As a result, a contact structure 204 including the first contact 202 and the second contact 203 may be formed in the hole 200.

A first adhesion layer 205 may be formed on the first insulating pattern 201 and the contact structure 204. The first adhesion layer 205 may include, e.g., titanium. An oxidation preventing layer 206 may be formed on the first adhesion layer 205. The oxidation preventing layer 206 may include, e.g., titanium aluminum nitride.

A lower electrode layer 207 may be formed on the oxidation preventing layer 206. The lower electrode layer 207 may include a conductive material, e.g., metal, polysilicon doped with impurities, conductive metal nitride, etc.

A ferroelectric layer 208 may be formed on the lower electrode layer 207. The ferroelectric layer 208 may include a ferroelectric material including titanium and oxygen. For example, the ferroelectric material may include one or more of PZT, SBT, BLT, PLZT, BST, etc.

A second adhesion layer 209 may be formed on the ferroelectric layer 208. The second adhesion layer 209 may include, e.g., an aluminum oxide. The second adhesion layer 209 may protect the ferroelectric layer 208. The second adhesion layer 209 may firmly attach a mask pattern 210, which may be formed subsequently, to the ferroelectric layer 208.

The second adhesion layer 209 including the aluminum oxide may be formed by, e.g., a chemical vapor deposition (CVD) process or an atomic layer deposition (ALD) process. A source gas used in forming the second adhesion layer 209 may include trimethylaluminum (TMA), which includes hydrogen. The aluminum oxide may be formed by a reaction having an equation as follows:

2 Al(CH₃)₃+O₃→Al₂O₃+3 C₂H₆

As described in the equation, trimethylaluminum and ethane (C₂H₆) include hydrogen. The ferroelectric layer 208 may be deteriorated by hydrogen in trimethylaluminum and/or ethane, which may form a dead layer 208a at a surface of the ferroelectric layer 208. The dead layer 208a may also be formed during subsequent formation of a silicon oxide layer on the ferroelectric layer 208, e.g., where a source gas used in forming the silicon oxide layer includes hydrogen.

A mask layer (not shown) may be formed on the second adhesion layer 209. The mask layer may include, e.g., oxide, nitride, oxynitride, etc. For example, the mask layer one or more of BPSG, PSG, USG, SOG, FOX, PE-TEOS, HDP-CVD oxide, silicon nitride, silicon oxynitride, etc. When the mask layer is formed using PE-TEOS, the mask layer may be formed at a relatively low temperature, e.g., about 200° C. A photolithography process may be performed on the mask layer, thereby transforming the mask layer into the mask pattern 210.

Referring to FIG. 10, the second adhesion layer 209, the ferroelectric layer 208, the lower electrode layer 207, the oxidation preventing layer 206 and the first adhesion layer 205 may be etched, e.g., using an anisotropic etch, using the mask pattern 210 as an etch mask. Thus, the second adhesion layer 209, the ferroelectric layer 208, the lower electrode 207, the oxidation preventing layer 206 and the first adhesion layer 205 may be transformed into a second adhesion pattern 215, a ferroelectric pattern 214, a lower electrode 213, an oxidation preventing pattern 212 and a first adhesion pattern 211, respectively. A size of the mask pattern 210 may decrease during the etching of the second adhesion layer 209, the ferroelectric layer 208, the lower electrode layer 207, the oxidation preventing layer 206 and the first adhesion layer 205. The dead layer 208a may be transformed into a dead pattern 214a as the ferroelectric layer 208 is transformed into the ferroelectric pattern 214.

Referring to FIG. 11, a capping layer 216 may be formed to cover the first insulating pattern 201, the mask pattern 210, the second adhesion pattern 215, the ferroelectric pattern 214, the lower electrode 213, the oxidation preventing pattern 212 and the first adhesion pattern 211. The capping layer 216 may protect the ferroelectric pattern 214. For example, the capping layer 216 may prevent hydrogen from deteriorating the ferroelectric pattern 214.

A second insulating layer 217 may be formed on the capping layer 216. The second insulating layer 217 may include, e.g., oxide, nitride, oxynitride, etc. For example, the second insulating layer 217 may include one or more of BPSG, PSG, USG, SOG, FOX, PE-TEOS, HDP-CVD oxide, silicon nitride, silicon oxynitride, etc.

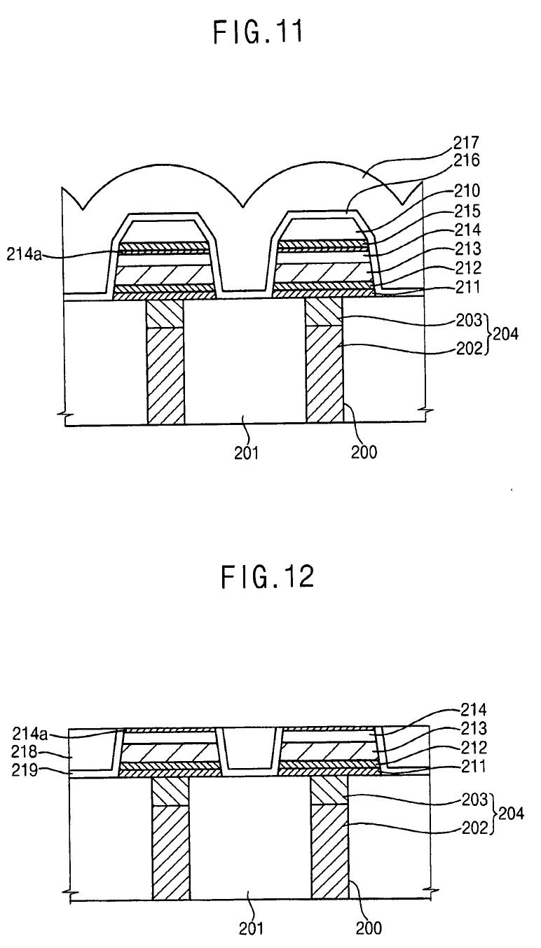

Referring to FIG. 12, a first CMP process may be performed on the second insulating layer 217, the capping layer 216, the mask pattern 210 and the second adhesion pattern 215. The first CMP process may be continued until the dead pattern 214a at the surface of the ferroelectric pattern 214 is exposed. Thus, the second insulating layer 217 and the capping layer 216 may be transformed into a second insulating pattern 218 and a capping pattern 219, respectively. The mask pattern 210 and the second adhesion pattern 215 may be removed by the first CMP process.

A slurry including ceria may be used in the first CMP process. Where the slurry includes ceria, a polishing rate of the second insulating layer 217 may be greater than that of the ferroelectric pattern 214 in the first CMP process. Thus, it may be possible to use the ferroelectric pattern 214 including the dead pattern 214a as a polishing stop pattern in the first CMP process.

A pH of the slurry may be about 5 to about 9. In an implementation, the pH of the slurry may be about 6 to about 8. Using a pH of less than about 5 may increase the polishing rate of the ferroelectric pattern 214. Using a pH of more than about 9 may also increase the polishing rate of the ferroelectric pattern 214. If the polishing rate of the ferroelectric pattern 214 in the slurry is increased, it may not be effective to use the ferroelectric pattern 214 as a polishing stop pattern.

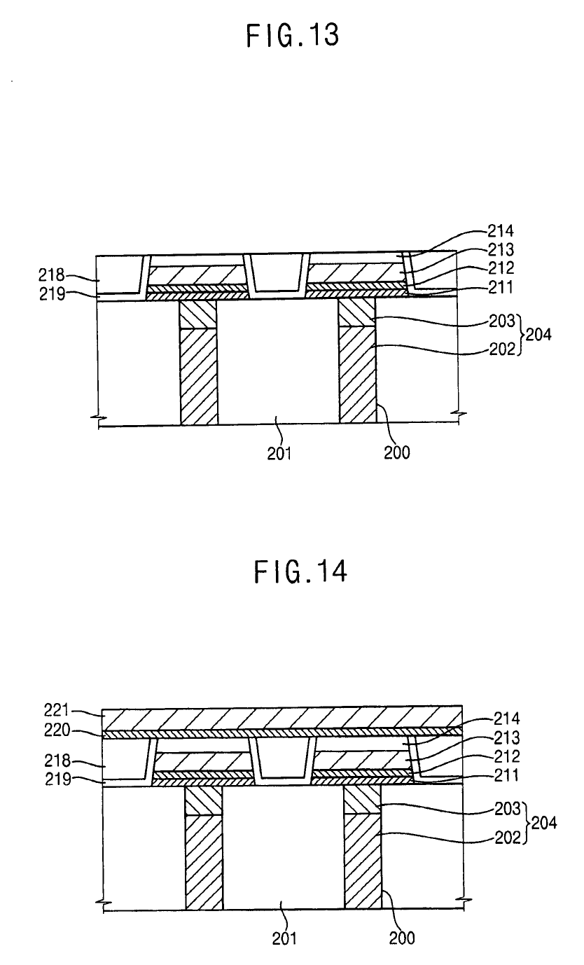

Referring to FIG. 13, a second CMP process may be performed on the ferroelectric pattern 214, the second insulating pattern 218 and the capping pattern 219. The second CMP process may be performed until the dead pattern 214a is removed. A slurry used in the second CMP process may be substantially the same as that used in the first CMP process. An electric reliability of the ferroelectric pattern 214 may be improved by removing the dead pattern 214a from the ferroelectric pattern 214.

Referring to FIG. 14, a curing layer 220 may be formed on the ferroelectric pattern 214, the second insulating pattern 218 and the capping pattern 219. The curing layer 220 may include a metal oxide having a perovskite structure, such as strontium ruthenium oxide. Hydrogen may not reach the ferroelectric pattern 214 through the curing layer 220.

An upper electrode layer 221 may be formed on the curing layer 220. The upper electrode layer 221 may include a conductive material, e.g., metal, polysilicon doped with impurities, conductive metal nitride, etc. The curing layer 220 may cure damage generated between the ferroelectric pattern 214 and the upper electrode layer 221.

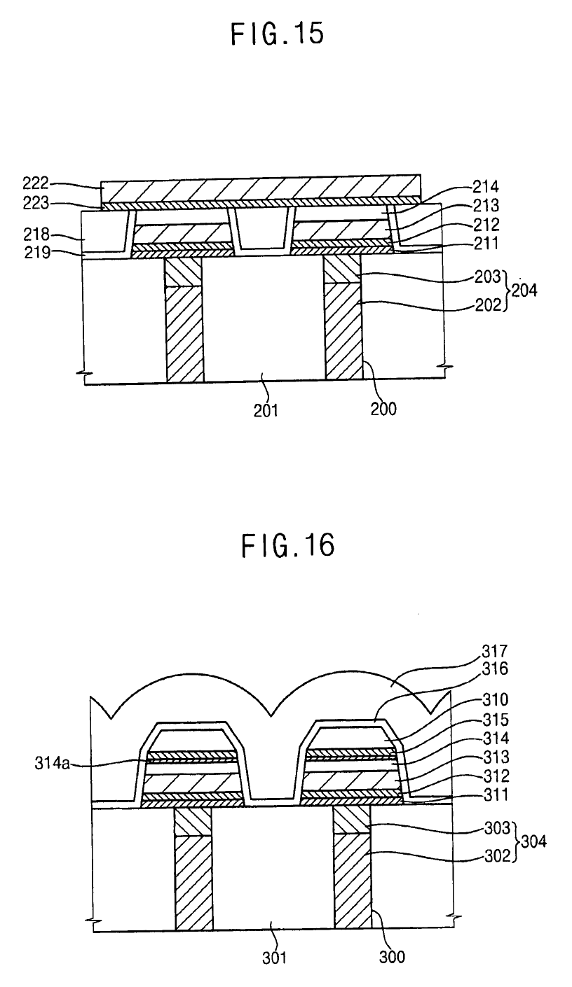

Referring to FIG. 15, the upper electrode layer 221 and the curing layer 220 may be etched to form an upper electrode 222 and a curing pattern 223, respectively. In an implementation, the upper electrode 222 may be electrically connected to two or more ferroelectric patterns 214. Thus, a ferroelectric capacitor structure that includes the lower electrode 213, the ferroelectric pattern 214 and the upper electrode 222 may be formed.

FIGS. 16-19 illustrate cross-sectional views of stages in a method of manufacturing a ferroelectric capacitor in accordance with a fourth embodiment of the present invention. Referring to FIG. 16, a ferroelectric structure including a first adhesion pattern 311, an oxidation preventing pattern 312, a lower electrode 313, a ferroelectric pattern 314, a second adhesion pattern 315, a capping layer 316 and a second insulating layer 317 may be formed on a first insulating pattern 301 having a hole 300, which may be filled with a contact structure 304 that includes first and second contacts 302 and 303. The ferroelectric structure may be formed using processes substantially the same as those described above in connection with FIGS. 9-11. A dead pattern 314a may be on a surface of the ferroelectric pattern 314.

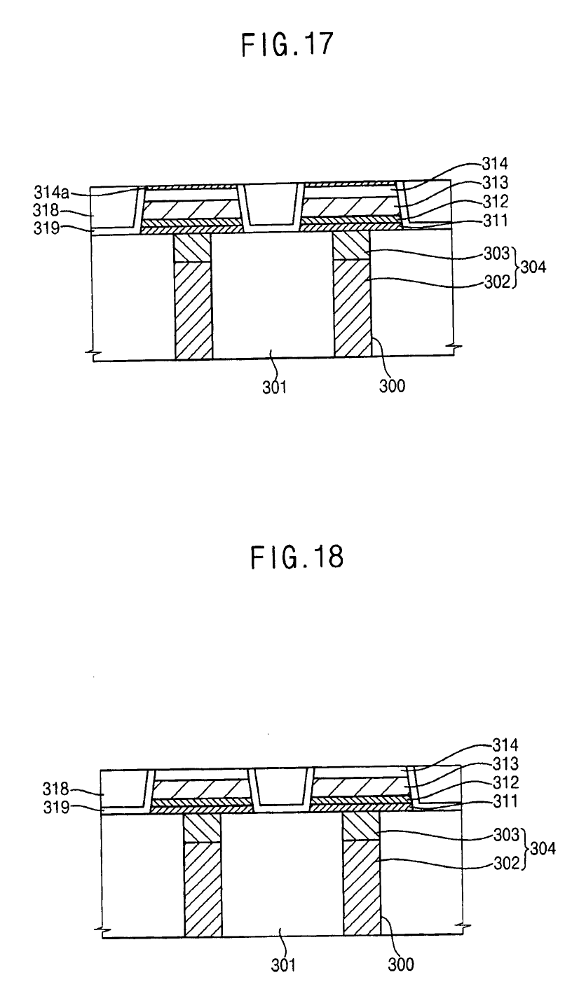

Referring to FIG. 17, a first CMP process may be performed on the second insulating layer 317, the capping layer 316, the mask pattern 310 and the second adhesion pattern 315. The first CMP process may be continued until the dead layer formed at the surface of the ferroelectric pattern 314 is exposed. Thus, the second insulating layer 317 and the capping layer 316 may be transformed into a second insulating pattern 318 and a capping pattern 319, respectively. The mask pattern 310 and the second adhesion pattern 315 may be removed by the first CMP process.

A slurry including ceria may be used in the first CMP process. Where the slurry includes ceria, a polishing rate of the second insulating layer 317 may be greater than that of the ferroelectric pattern 314 in the first CMP process. Thus, it may be possible to use the ferroelectric pattern 314 as a polishing stop pattern in the first CMP process.

A pH of the slurry may be about 5 to about 9. In an implementation, the pH of the slurry may be about 6 to about 8. Using a pH of less than about 5 may increase the polishing rate of the ferroelectric pattern 314. Using a pH of more than about 9 may also increase the polishing rate of the ferroelectric pattern 314. If the polishing rate of the ferroelectric pattern 314 in the slurry is unduly increased, it may not be effective to use the ferroelectric pattern 314 as a polishing stop pattern.

Referring to FIG. 18, a second CMP process may be performed on the ferroelectric pattern 314, the second insulating pattern 318 and the capping pattern 319. The second CMP process may be performed until the dead pattern 314a is removed.

A slurry including silica may be used in the second CMP process. Where the slurry includes silica, a polishing rate of the ferroelectric pattern 314 may increase. Thus, the dead pattern 314a at the surface of the ferroelectric pattern 314 may be rapidly removed. An electric reliability of the ferroelectric pattern 314 may be improved by removing the dead pattern 314a from the ferroelectric pattern 314 using the second CMP process.

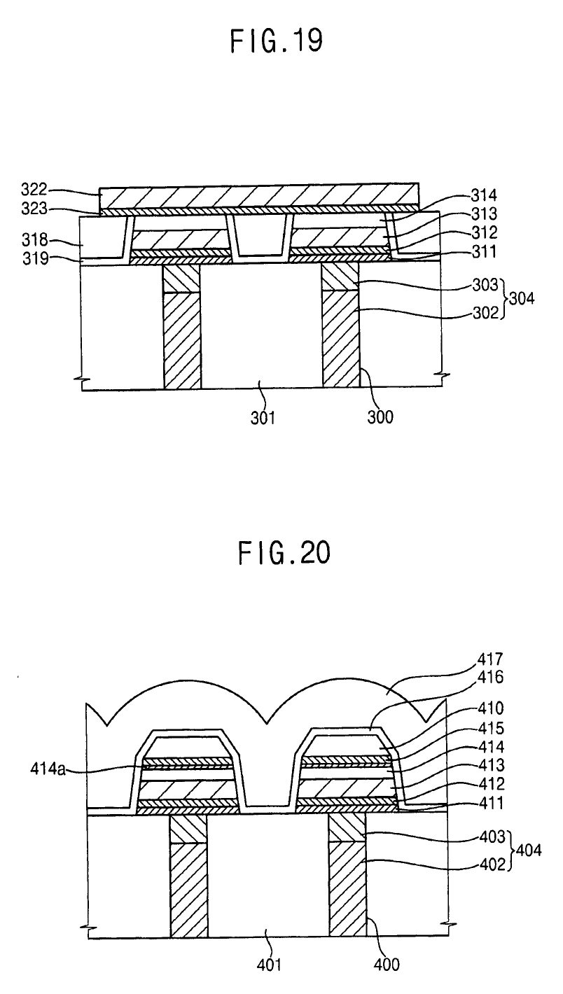

Referring to FIG. 19, a curing pattern 323 and an upper electrode 322 may be formed on the ferroelectric pattern 314, the second insulating pattern 318 and the capping pattern 319 by performing using processes substantially the same as those described above in connection with FIGS. 13 and 14. Thus, a ferroelectric capacitor including the lower electrode 313, the ferroelectric pattern 314 and the upper electrode 322 may be formed.

FIGS. 20-23 illustrate cross-sectional views of stages in a method of manufacturing a ferroelectric capacitor in accordance with a fifth embodiment of the present invention. Referring to FIG. 20, a ferroelectric structure including a first adhesion pattern 411, an oxidation preventing pattern 412, a lower electrode 413, a ferroelectric pattern 414, a second adhesion pattern 415, a mask pattern 410, a capping layer 416 and a second insulating layer 417 may be formed on a first insulating pattern 401 having a hole 400, which may be filled with a contact structure 404 that includes a first contact 402 and a second contact 403. The ferroelectric structure may be formed using processes substantially the same as those described above in connection with FIGS. 9-11.

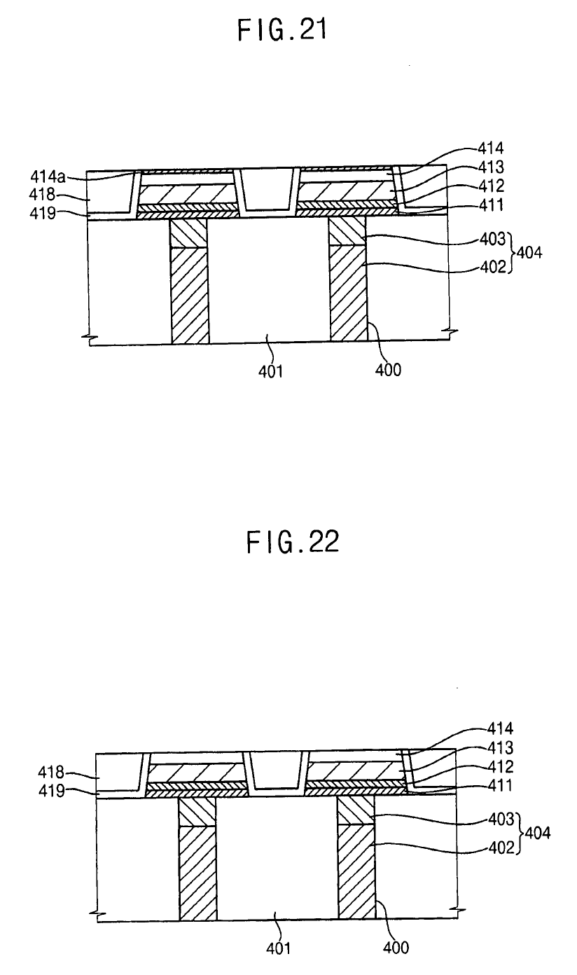

Referring to FIG. 21, a CMP process may be performed on the second insulating layer 417, the capping layer 416, the mask pattern 410 and the second adhesion pattern 415. The CMP process may be continued until a dead pattern 414a at a surface of the ferroelectric pattern 414 is exposed. Thus, the second insulating layer 417 and the capping layer 416 may be transformed into a second insulating pattern 418 and a capping pattern 419, respectively. The mask pattern 410 and the second adhesion pattern 415 may be removed by the CMP process.

A slurry including ceria may be used in the CMP process. Where the slurry includes ceria, a polishing rate of the second insulating layer 417 may be greater than a polishing rate of the ferroelectric pattern 414 in the CMP process. Thus, the ferroelectric pattern 414 may be used as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 414. Using a pH of more than about 9 may also increase the polishing rate of the ferroelectric pattern 414. If the polishing rate of the ferroelectric pattern 414 in the slurry is unduly increased, it may not be effective to use the ferroelectric pattern 414 as a polishing stop pattern.

Referring to FIG. 22, an etch-back may be performed on the ferroelectric pattern 414, the second insulating pattern 418 and the capping pattern 419, e.g., using an etching gas including fluorine. In an implementation, the etching gas may include fluorine-substituted carbon. For example, the etching gas may include a moiety such as carbon monofluoride (CF), carbon difluoride (CF₂) or carbon trifluoride (CF₃), a compound such as carbon tetrafluoride (CF₄), combinations thereof, etc. The etch-back process may be performed until the dead pattern 414a is removed from the ferroelectric pattern 414.

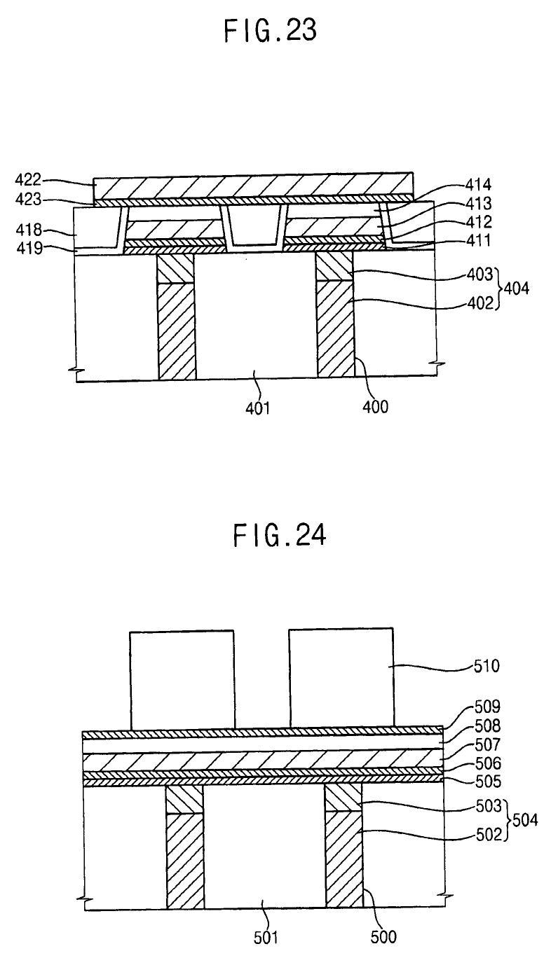

Referring to FIG. 23, a curing pattern 423 and an upper electrode 422 may be formed on the ferroelectric pattern 414, the second insulating pattern 418 and the capping pattern 419 by performing processes substantially the same as those described above in connection with FIGS. 13 and 14. Thus, a ferroelectric capacitor including the lower electrode 413, the ferroelectric pattern 414 and the upper electrode 422 may be formed.

FIGS. 24-29 illustrate cross-sectional views of stages in a method of manufacturing a ferroelectric capacitor in accordance with a sixth embodiment of the present invention. Referring to FIG. 24, a ferroelectric structure including a first adhesion layer 505, an oxidation preventing layer 506, a lower electrode layer 507 and a ferroelectric layer 508 may be formed on a first insulating pattern 501 having a hole 500, which may be filled with a contact structure 504 having first and second contacts 502 and 503. The ferroelectric structure may be formed by performing processes substantially the same as those described above in connection with FIG. 9.

A second adhesion layer 509 may be formed on the ferroelectric layer 508. The second adhesion layer 509 may be formed using a metal oxide having a perovskite structure, e.g., strontium ruthenium oxide or chromium ruthenium oxide. The second adhesion layer 509 may be formed using a physical vapor deposition (PVD) process such as a sputtering process. Where the second adhesion layer 509 including the metal oxide is formed by the PVD process, the process may not employ a source gas including hydrogen. Thus, a dead layer may not be formed at a surface of the ferroelectric layer 508.

The second adhesion layer 509 may firmly fix a mask pattern 510, which may be formed subsequently, to the ferroelectric layer 508. In addition, hydrogen may not reach the ferroelectric pattern 508 through the second adhesion layer 509 during subsequent processes because the second adhesion layer 509 may include the metal oxide having the perovskite structure.

A mask layer (not shown) may be formed on the second adhesion layer 509. The mask layer may include, e.g., oxide, nitride, oxynitride, etc. For example, the mask layer may include one or more of BPSG, PSG, USG, SOG, FOX, PE-TEOS, HDP-CVD oxide, silicon nitride, silicon oxynitride, etc. Where the mask layer is formed using PE-TEOS, the mask layer may be formed at a relatively low temperature, e.g., about 200° C. A photolithography process may be performed on the mask layer, thereby transforming the mask layer into the mask pattern 510.

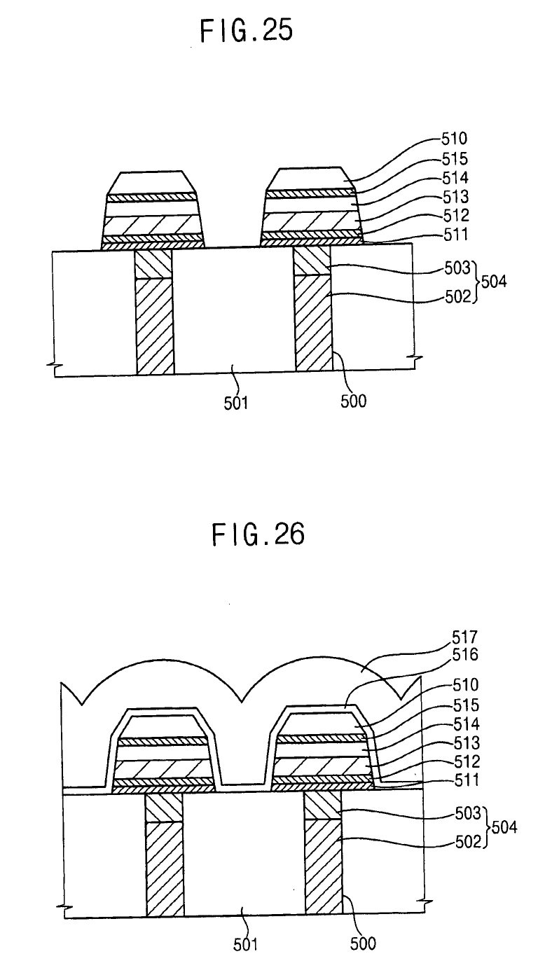

Referring to FIG. 25, the second adhesion layer 509, ferroelectric layer 508, the lower electrode layer 507, the oxidation preventing layer 506 and the first adhesion layer 505 may be etched, e.g., using an anisotropic etch, using the mask pattern 510 as an etch mask. Thus, the second adhesion layer 509, the ferroelectric layer 508, the lower electrode 507, the oxidation preventing layer 506 and the first adhesion layer 505 may be transformed into a second adhesion pattern 515, a ferroelectric pattern 514, a lower electrode 513, an oxidation preventing pattern 512 and a first adhesion pattern 511, respectively. A size of the mask pattern 510 may be decreased during the etching of the second adhesion layer 509, the ferroelectric layer 508, the lower electrode layer 507, the oxidation preventing layer 506 and the first adhesion layer 505.

Referring to FIG. 26, a capping layer 516 covering the first insulating pattern 501, the mask pattern 510, the second adhesion pattern 515, the ferroelectric pattern 514, the lower electrode 513, the oxidation preventing pattern 512 and the first adhesion pattern 511 may be formed. The capping layer 516 may protect the ferroelectric pattern 514. For example, the capping layer 516 may prevent hydrogen from deteriorating the ferroelectric pattern 514.

A second insulating layer 517 may be formed on the capping layer 516. The second insulating layer 517 may include, e.g., oxide, nitride, oxynitride, etc. For example, the second insulating layer 517 may include one or more of BPSG, PSG, USG, SOG, FOX, PE-TEOS, HDP-CVD oxide, silicon nitride, silicon oxynitride, etc.

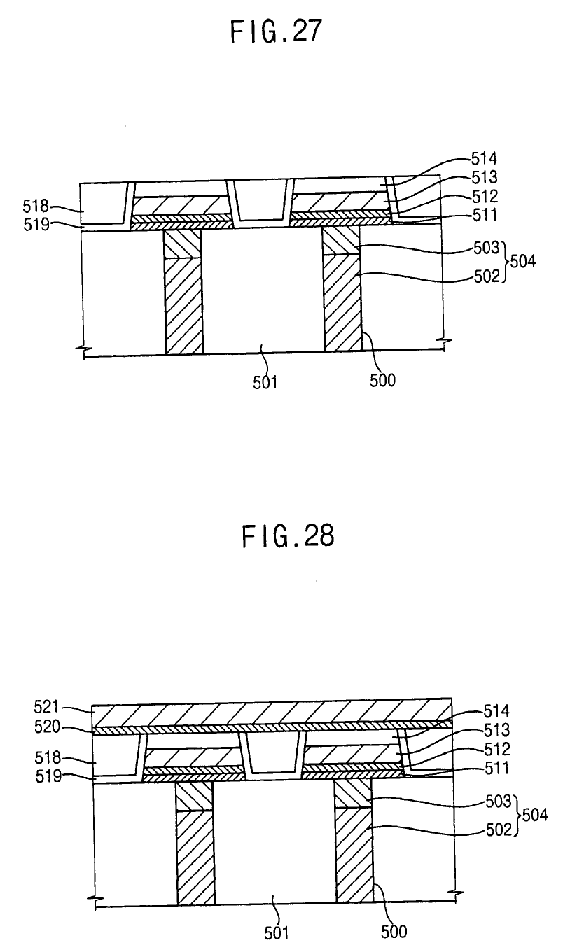

Referring to FIG. 27, a CMP process may be performed on the second insulating layer 517, the capping layer 516, the mask pattern 510 and the second adhesion pattern 515. The CMP process may be continued until the ferroelectric pattern 514 is exposed. Thus, the second insulating layer 517 and the capping layer 516 may be transformed into the second insulating pattern 518 and the capping pattern 519. The mask pattern 510 and the second adhesion pattern 515 may be removed by the CMP process.

A slurry including ceria may be used in the CMP process. Where the slurry includes ceria, a polishing rate of the second insulating layer 517 may be greater than a polishing rate of the ferroelectric pattern 514 in the CMP process. Thus, the ferroelectric pattern 514 may be used as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 514. Using a pH of more than about 9 may also increase the polishing rate of the ferroelectric pattern 514. If the polishing rate of the ferroelectric pattern 514 in the slurry is unduly increased, it may not be effective to use the ferroelectric pattern 514 as a polishing stop pattern.

The second adhesion pattern 515 may be efficiently removed by the CMP process, because a polishing rate of the second adhesion pattern 515 including the metal oxide such as strontium ruthenium oxide or chromium ruthenium oxide may be relatively large in the CMP process.

Referring to FIG. 28, a curing layer 520 may be formed on the ferroelectric pattern 514, the second insulating pattern 518 and the capping pattern 519. The curing layer 520 may be formed using a metal oxide having a perovskite structure, e.g., strontium ruthenium oxide. The curing layer 520 may prevent hydrogen from reaching the ferroelectric layer 508 through the curing layer 520 in subsequent processes.

An upper electrode layer 521 may be formed on the curing layer 520. The upper electrode layer 521 may include a conductive material, e.g., metal, polysilicon doped with impurities, conductive metal nitride, etc. The curing layer 520 may cure defects that may be generated between the ferroelectric pattern 514 and the upper electrode layer.

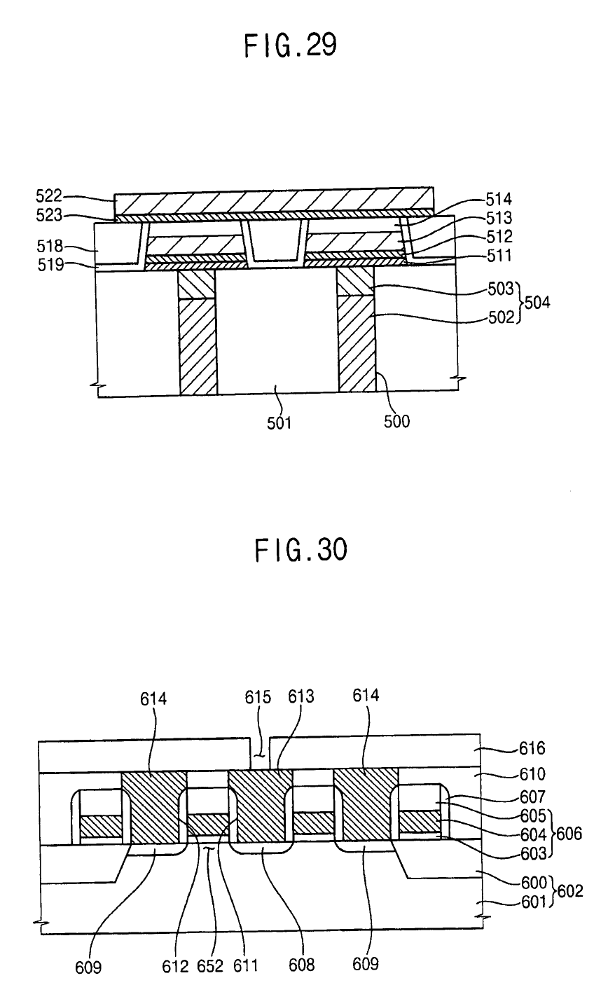

Referring to FIG. 29, the upper electrode layer 521 and the curing layer 520 may be etched to form an upper electrode 522 and a curing pattern 523, respectively. In an implementation, the upper electrode 522 may electrically connect to two or more ferroelectric patterns 514. Thus, a ferroelectric capacitor including a lower electrode 513, a ferroelectric pattern 514 and an upper electrode 522 may be formed.

FIGS. 30-39 illustrate cross-sectional views of stages in a method of manufacturing a ferroelectric memory device in accordance with a seventh embodiment of the present invention. Referring to FIG. 30, an isolation layer may be formed in a surface of a wafer, e.g., using an isolation process such as a shallow trench isolation (STI) process. The isolation layer may correspond to a field region 600. A portion of the wafer encompassed by the field region 600 may correspond to an active region 601. Thus, a semiconductor substrate 602 having the field region 600 and the active region 601 may be formed.

A gate oxide layer, a gate electrode layer and a gate mask layer (not shown) may be successively formed on the semiconductor substrate 602. The gate mask layer, the gate electrode layer and the gate oxide layer may be successively etched to form a gate structure 606 including a gate oxide pattern 603, a gate electrode 604 and a gate mask 605.

A spacer 607 may be formed on a sidewall of the gate structure 606. An impurity may be implanted into a surface of the active region 601, e.g., using the spacer 607 and the gate mask 605 together as an ion implantation mask. Thus, a first source/drain region 608 and a second source/drain region 609 may be formed in the surface of the active region 601. A portion of the active region 601 located between the first source/drain region 608 and the second source/drain region 609 may correspond to a channel region 652.

A first insulating layer (not shown) may be formed on the field region 600, the first source/drain region 608 and the second source/drain region 609, and may cover the gate structure 606. The first insulating layer may be etched to form a first insulating pattern 610 having a first opening 611 and a second opening 612. The first opening 611 and the second opening 612 may expose the first source/drain region 608 and the second source/drain region 609, respectively.

A first conductive layer (not shown) may be formed on the first insulating pattern 610 to fill up the first opening 611 and the second opening 612. The first conductive layer may be planarized until the first insulating pattern 610 is exposed. Thus, a first pad 613 and a second pad 614 may be formed in the first opening 611 and the second opening 612, respectively.

A second insulating layer (not shown) may be formed on the first insulating pattern 610, the first pad 613 and the second pad 614. The second insulating layer may be etched to form a preliminary second insulating pattern 616 having a third opening 615 that exposes the first pad 613.

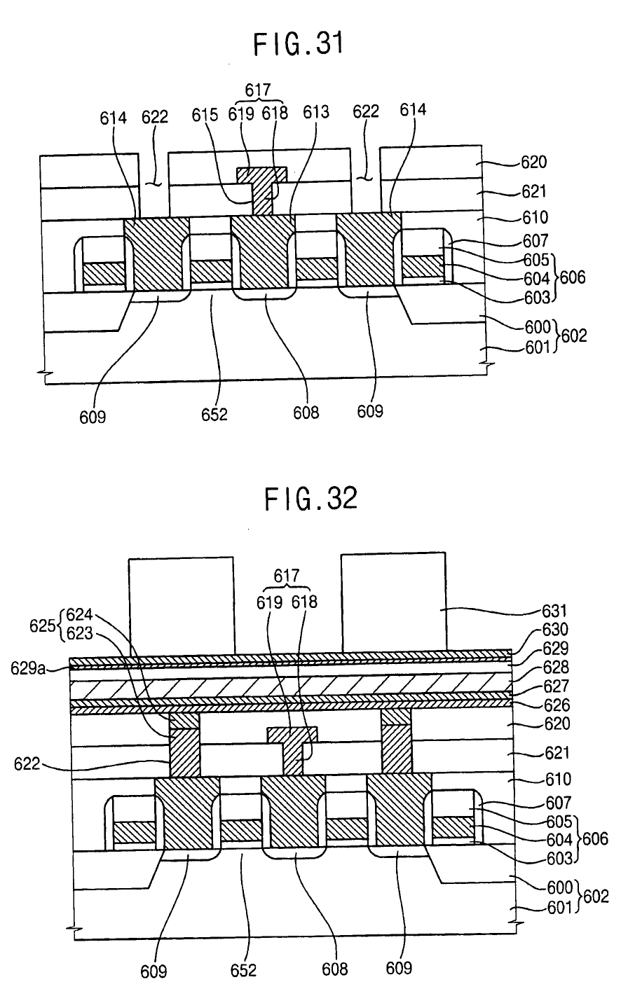

Referring to FIG. 31, a second conductive layer (not shown) may be formed on the preliminary second insulating pattern 616 to fill up the third opening 615. The second conductive layer may be etched to form a bit line 617 filling up the third opening 615. The bit line 617 may have a lower portion 618 filling up the third opening 615 and an upper portion 619 located on the preliminary second insulating pattern 616.

A third insulating layer (not shown) may be formed on the bit line 617 and the preliminary second insulating pattern 616, and the third insulating layer and the preliminary second insulating pattern 616 may be etched. Thus, the third insulating layer and the preliminary second insulating pattern 616 may be transformed into a third insulating pattern 620 and a second insulating pattern 621, respectively. The third insulating pattern 620 and the second insulating pattern 621 together may have a fourth opening 622 exposing the second pad 614.

Referring to FIG. 32, a third conductive layer (not shown) may be formed on the third insulating pattern 620 to fill up the fourth opening 622. The third conductive layer may include, e.g., tungsten. The third conductive layer may be planarized until the third insulating pattern 620 is exposed. Thus, a preliminary first contact (not shown) filling up the fourth opening 622 may be formed.

Where the preliminary first contact includes tungsten, dishing may occur at an upper portion of the preliminary first contact. Thus, a contact structure 625 including a second contact 624 may be formed to prevent the dishing. In detail, an etch-back process may be performed on the preliminary first contact to remove an upper portion of the preliminary first contact, thereby transforming the preliminary first contact into a first contact 623. The first contact 623 may partially fill the fourth opening 622. A fourth conductive layer (not shown) may be formed on the third insulating pattern 620 to fill up the fourth opening 622. The fourth conductive layer may include, e.g., tungsten nitride. The fourth conductive layer may be planarized until the third insulating pattern 620 is exposed. Thus, the second contact 624 filling up the fourth opening 622 may be formed on the first contact 623. Thus, the contact structure 625 including the first contact 623 and the second contact 624 may be formed in the fourth opening 622.

A first adhesion layer 626 may be formed on the third insulating pattern 620 and the contact structure 625. The first adhesion layer 626 may include, e.g., titanium. An oxidation preventing layer 627 may be formed on the first adhesion layer 626. The oxidation preventing layer 627 may include, e.g., titanium aluminum nitride.

A lower electrode layer 628 may be formed on the oxidation preventing layer 627. The lower electrode layer 628 may include a conductive material, e.g., metal, polysilicon doped with impurities, conductive metal nitride, etc.

A ferroelectric layer 629 may be formed on the lower electrode layer 628. The ferroelectric layer 629 may include a ferroelectric material including titanium and oxygen. For example, the ferroelectric material may include one or more of PZT, SBT, BLT, PLZT, BST, etc.

A second adhesion layer 630 may be formed on the ferroelectric layer 629. The second adhesion layer 630 may include, e.g., aluminum oxide, and may protect the ferroelectric layer 629. In addition, the second adhesion layer 630 may firmly attach a mask pattern 631, which may be formed subsequently, to the ferroelectric layer 629.

The second adhesion layer 630 including the aluminum oxide may be formed by a CVD process, an ALD process, etc. A source gas used in forming the second adhesion layer 630 may include TMA, which includes hydrogen. The aluminum oxide may be formed by a reaction having an equation as follows:

2 Al(CH₃)₃+O₃→Al₂O₃+3 C₂H₆

As described in the equation, trimethylaluminum and ethane (C₂H₆) include hydrogen. The ferroelectric layer 629 may be deteriorated by hydrogen included in trimethylaluminum and/or ethane, which may form a dead layer 629a at a surface of the ferroelectric layer 629. The dead layer 629a may also be formed during subsequent formation of a silicon oxide layer on the ferroelectric layer 629, e.g., where a source gas used in forming the silicon oxide layer includes hydrogen.

A mask layer (not shown) may be formed on the second adhesion layer 630. The mask layer may include, e.g., oxide, nitride, oxynitride, etc. For example, the mask layer may include one or more of BPSG, PSG, USG, SOG, FOX, PE-TEOS, HDP-CVD oxide, silicon nitride, silicon oxynitride, etc. When the mask layer is formed using PE-TEOS, the mask layer may be formed at a relatively low temperature, e.g., about 200° C. A photolithography process may be performed on the mask layer, thereby transforming the mask layer into the mask pattern 631.

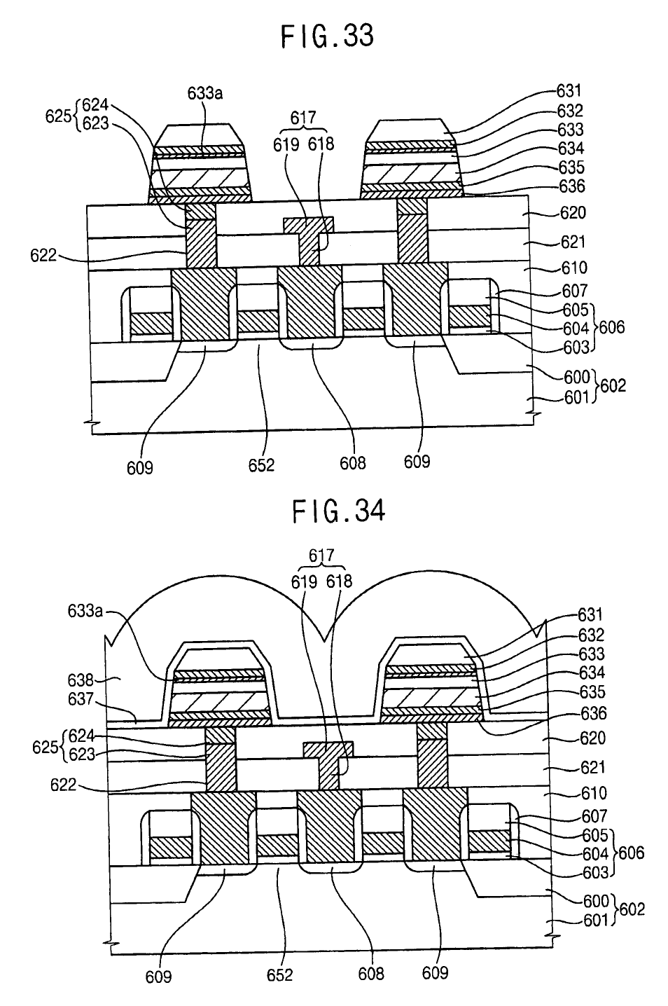

Referring to FIG. 33, the second adhesion layer 630, the ferroelectric layer 629, the lower electrode layer 628, the oxidation preventing layer 627 and the first adhesion layer 626 may be etched, e.g., using an anisotropic etch, using the mask pattern 631 as an etch mask. Thus, the second adhesion layer 630, the ferroelectric layer 629, the lower electrode 628, the oxidation preventing layer 627 and the first adhesion layer 626 may be transformed into a second adhesion pattern 632, a ferroelectric pattern 633, a lower electrode 634, an oxidation preventing pattern 635 and a first adhesion pattern 636, respectively. A size of the mask pattern 631 may decrease during the etching of the second adhesion layer 630, the ferroelectric layer 629, the lower electrode layer 628, the oxidation preventing layer 627 and the first adhesion layer 626. The dead layer 629a may be transformed into a dead pattern 633a as the ferroelectric layer 629 is transformed into the ferroelectric pattern 633.

Referring to FIG. 34, a capping layer 637 covering the third insulating pattern 620, the mask pattern 631, the second adhesion pattern 632, the ferroelectric pattern 633, the lower electrode 634, the oxidation preventing pattern 635 and the first adhesion pattern 636 may be formed. The capping layer 637 may protect the ferroelectric pattern 633. For example, the capping layer 637 may prevent hydrogen from deteriorating the ferroelectric pattern 633.

A fourth insulating layer 638 may be formed on the capping layer 637. The fourth insulating layer 638 may include, e.g., oxide, nitride, oxynitride, etc. For example, the fourth insulating layer 638 may include one or more of BPSG, PSG, USG, SOG, FOX, PE-TEOS, HDP-CVD oxide, silicon nitride, silicon oxynitride, etc.

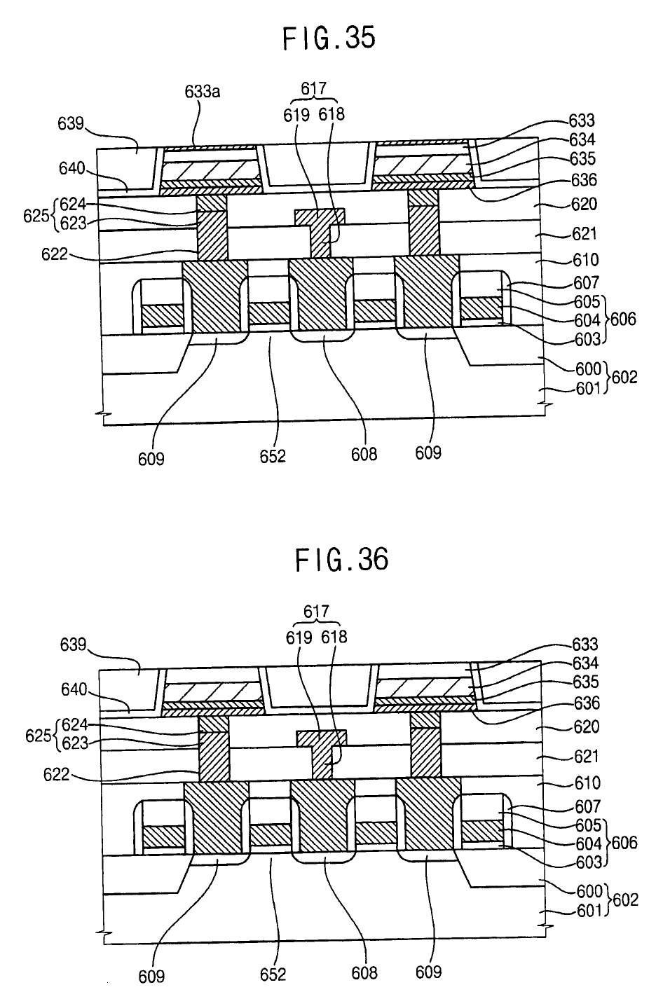

Referring to FIG. 35, a first CMP process may be performed on the fourth insulating layer 638, the capping layer 637, the mask pattern 631 and the second adhesion pattern 632. The first CMP process may be continued until the ferroelectric pattern 633 is exposed. Thus, the fourth insulating layer 638 and the capping layer 637 may be transformed into a fourth insulating pattern 639 and a capping pattern 640, respectively. The mask pattern 631 and the second adhesion pattern 632 may be removed by the first CMP process.

A slurry including ceria may be used in the first CMP process. Where the slurry includes the ceria, a polishing rate of the fourth insulating layer 638 may be greater than a polishing rate of the ferroelectric pattern 633 in the first CMP process. Thus, it may be possible to use the ferroelectric pattern 633 as a polishing stop pattern in the first CMP process.

A pH of the slurry may be about 5 to about 9. In an implementation, the pH of the slurry may be about 6 to about 8. Using a pH of less than about 5 may increase the polishing rate of the ferroelectric pattern 633. Using a pH of more than about 9 may also increase the polishing rate of the ferroelectric pattern 633. If the polishing rate of the ferroelectric pattern 633 in the slurry is increased, it may not be effective to use the ferroelectric pattern 633 as a polishing stop pattern.

Referring to FIG. 36, a second CMP process may be performed on the ferroelectric pattern 633, the fourth insulating pattern 639 and the capping pattern 632. The second CMP process may be performed until the dead pattern 633a is removed. A slurry used in the second CMP process may be substantially the same as the slurry used in the first CMP process. An electric reliability of the ferroelectric pattern 633 may be increased by removing the dead pattern 633a from the ferroelectric pattern 633.

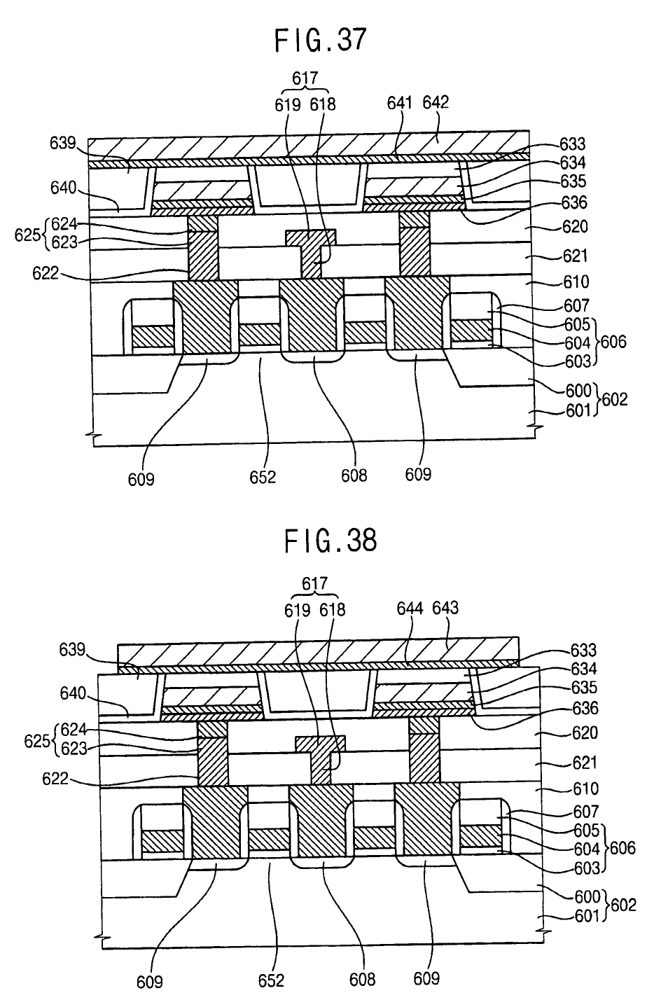

Referring to FIG. 37, a curing layer 641 may be formed on the ferroelectric pattern 633, the fourth insulating pattern 639 and the capping pattern 640. The curing layer 641 may include a metal oxide having a perovskite structure, such as strontium ruthenium oxide. The curing layer 641 may prevent hydrogen from reaching the ferroelectric layer 633 through the curing layer 641 in subsequent processes.

An upper electrode layer 642 may be formed on the curing layer 641. The upper electrode layer 642 may include a conductive material, e.g., metal, polysilicon doped with impurities, conductive metal nitride, etc.

Referring to FIG. 38, the upper electrode layer 642 and the curing layer 641 may be successively etched to form an upper electrode 643 and a curing pattern 644. The upper electrode 643 may be electrically connected to two or more ferroelectric patterns 633. Thus, a ferroelectric memory device including a transistor and a ferroelectric capacitor may be formed. The transistor may include the channel region 652, the first source/drain region 608, the second source/drain region 609, the gate oxide pattern 603 and the gate electrode 604. The ferroelectric capacitor may include the lower electrode 634, the ferroelectric pattern 633, the curing pattern 632 and the upper electrode 643.

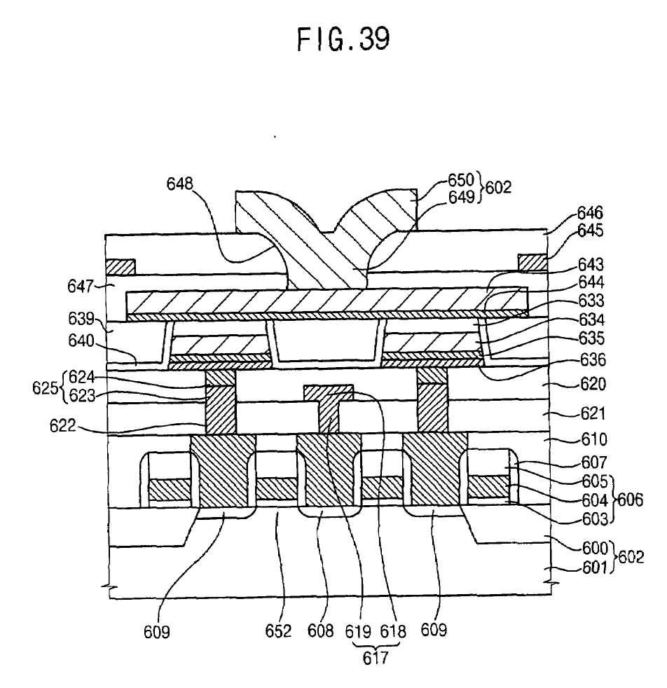

Referring to FIG. 39, a fifth insulating layer (not shown) may be formed on the fourth insulating pattern 639, the curing pattern 632 and the upper electrode 643. A word line 645 may be formed on the fifth insulating layer. A sixth insulating layer (not show) may be formed on the fifth insulating layer and the word line 645. The sixth insulating layer and the fifth insulating layer may be successively etched to transform them into a sixth insulating pattern 646 and a fifth insulating pattern 647, respectively. The sixth insulating pattern 646 and the fifth insulating pattern 647 together may have a fifth opening 648 exposing the upper electrode 643.

A fifth conductive layer (not shown) may be formed on the sixth insulating pattern 646 to fill the fifth opening 648. The fifth conductive layer is etched to form a wire 651. The wire 651 may have a lower portion filling up the fifth opening 648 and an upper portion located on the lower portion 649 and the sixth insulating pattern 646.

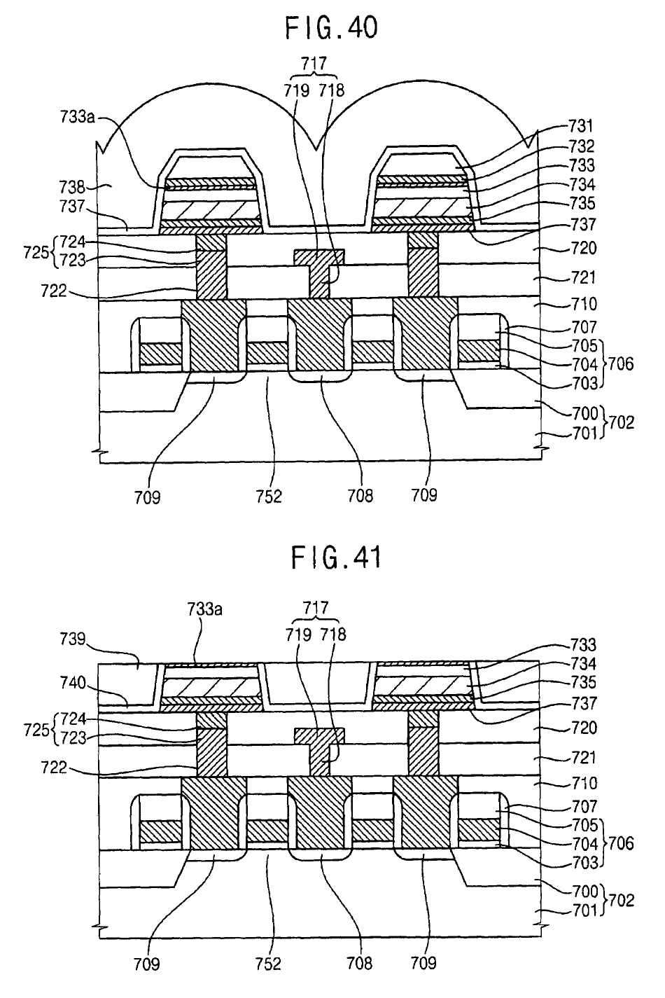

FIGS. 40-43 illustrate cross-sectional views of stages in a method of manufacturing a ferroelectric memory device in accordance with a eighth embodiment of the present invention. Referring to FIG. 40, a structure substantially the same as that illustrated in FIG. 34 may be formed by performing processes substantially the same as those described above in connection with FIGS. 30-34. A dead pattern 733a may be formed at a surface of a ferroelectric pattern 733.

Referring to FIG. 41, a first CMP process may be performed on a fourth insulating layer 738, a capping layer 737, a mask pattern 731 and a second adhesion pattern 732. The first CMP process may be continued until the ferroelectric pattern 733 is exposed. Thus, the fourth insulating layer 738 and the capping layer 737 may be transformed into a fourth insulating pattern 739 and a capping pattern 740. The mask pattern 731 and the second adhesion pattern 732 may be removed by the first CMP process.

A slurry including ceria may be used in the first CMP process. Where the slurry includes ceria, a polishing rate of the fourth insulating layer 738 may be greater than a polishing rate of the ferroelectric pattern 733 in the first CMP process. Thus, it may be possible to use the ferroelectric pattern 733 as a polishing stop pattern in the first CMP process.

A pH of the slurry may be about 5 to about 9. In an implementation, the pH of the slurry may be about 6 to about 8. Using a pH of less than about 5 may increase the polishing rate of the ferroelectric pattern 733. Using a pH of more than about 9 may also increase the polishing rate of the ferroelectric pattern 733. If the polishing rate of the ferroelectric pattern 733 in the slurry is unduly increased, it may not be effective to use the ferroelectric pattern 733 as a polishing stop pattern.

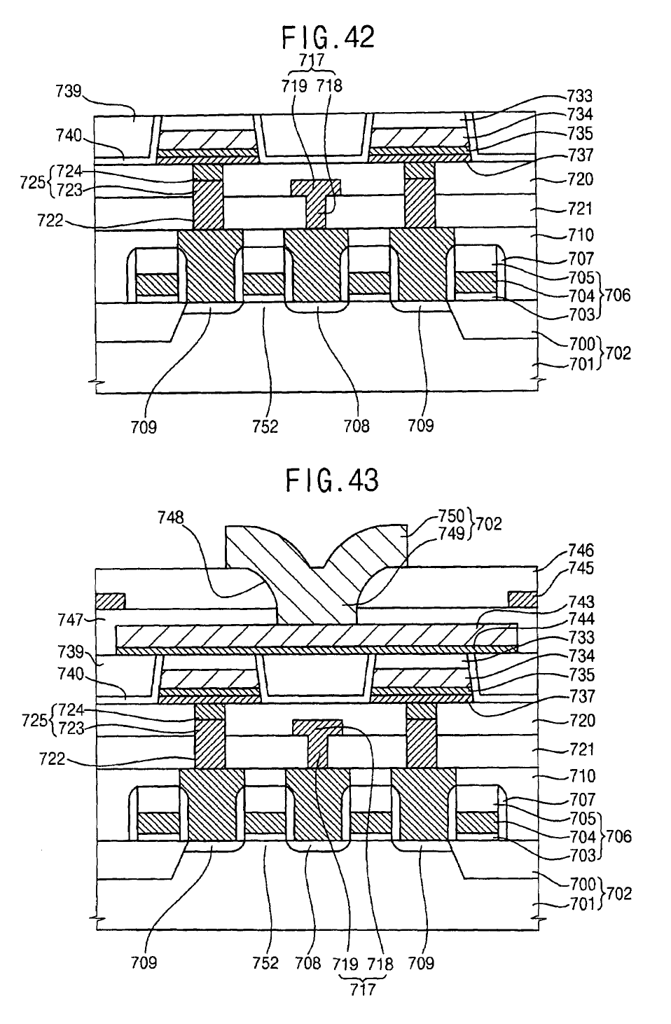

Referring to FIG. 42, a second CMP process may be performed on the ferroelectric pattern 733, the second insulating pattern 739 and the capping pattern 740. The second CMP process may be performed until the dead pattern 733a is removed.

A slurry including silica may be used in the second CMP process. When the slurry includes silica, a polishing rate of the ferroelectric pattern 733 may be increased. Thus, the dead layer formed at the surface of the ferroelectric pattern 733 may be rapidly removed. An electric reliability of the ferroelectric pattern 733 may be improved by removing the dead pattern 733a from the ferroelectric pattern using the second CMP process.

Referring to FIG. 43, a curing pattern 744, an upper electrode 743, a fifth insulating pattern 747, a word line 745, a sixth insulating pattern 746 and a wire 702 may be formed by processes substantially the same as those described above in connection with FIGS. 37-39. The wire 702 may be located in a fifth hole 748, and may include a lower portion 749 and an upper portion 750.

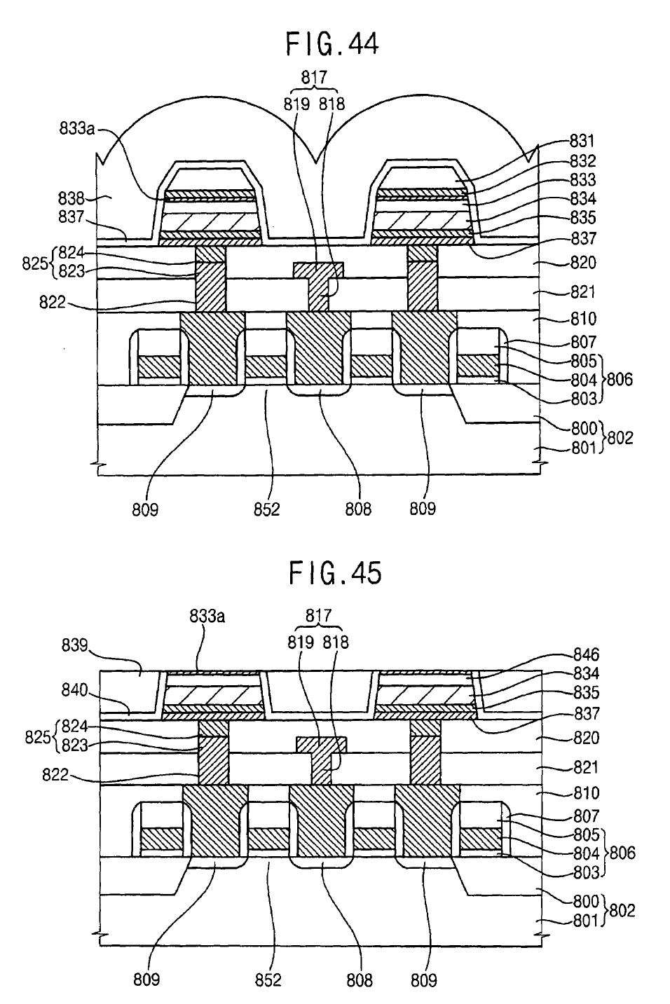

FIGS. 44-47 illustrate cross-sectional views of stages in a method of manufacturing a ferroelectric memory device in accordance with an ninth embodiment of the present invention. Referring to FIG. 44, a structure substantially the same as that illustrated in FIG. 34 may be formed by performing processes substantially the same as those described above in connection with FIGS. 30-34. A dead pattern 833a may be formed at a surface of a ferroelectric pattern 833.

Referring to FIG. 45, a CMP process may be performed on a fourth insulating layer 838, a capping layer 837, a mask pattern 831 and a second adhesion pattern 832. The CMP process may be continued until the ferroelectric pattern 833 is exposed. Thus, the fourth insulating layer 838 and the capping layer 837 may be transformed into a fourth insulating pattern 839 and a capping pattern 840, respectively. The mask pattern 831 and the second adhesion pattern 832 may be removed by the CMP process.

A slurry including ceria may be used in the CMP process. Where the slurry includes ceria, a polishing rate of the second insulating layer 833 may be greater than a polishing rate of the ferroelectric pattern 833 in the CMP process. Thus, the ferroelectric pattern 833 may be used as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 833. Using a pH of more than about 9 may also increase the polishing rate of the ferroelectric pattern 833. If the polishing rate of the ferroelectric pattern 833 in the slurry is unduly increased, it may not be effective to use the ferroelectric pattern 833 as a polishing stop pattern.

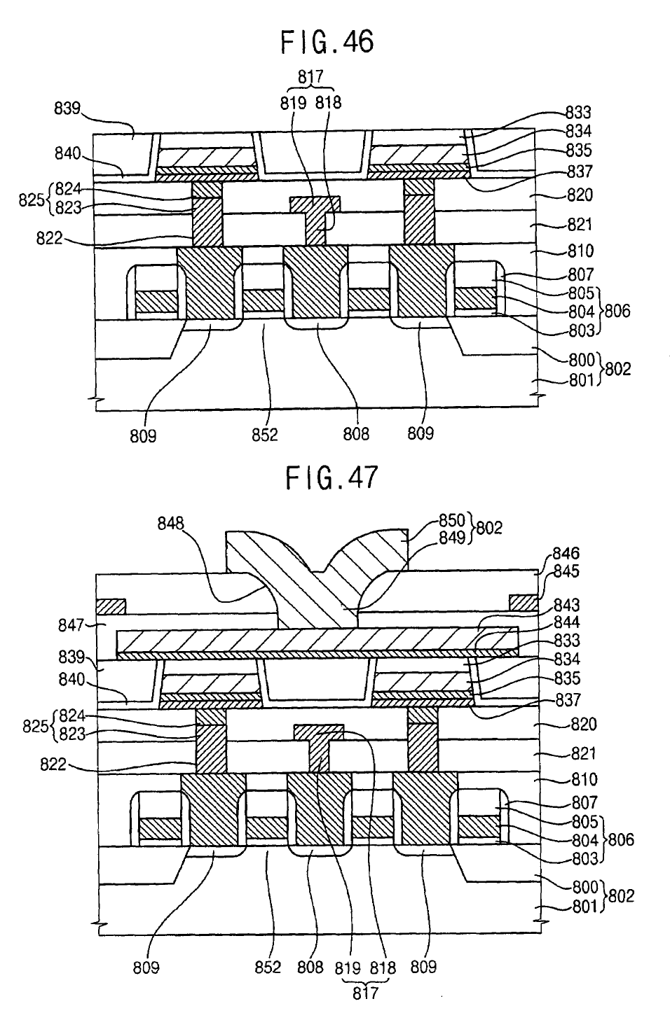

Referring to FIG. 46, an etch-back may be performed on the ferroelectric pattern 833, the second insulating pattern 839 and the capping pattern 840, e.g., using an etching gas including fluorine. The etching gas may include a carbon fluoride. In an implementation, the etching gas may include fluorine-substituted carbon. For example, the etching gas may include a moiety such as CF, CF₂ or CF₃, a compound such as CF₄, combinations thereof, etc. The etch-back process may be performed until the dead pattern 833a is removed from the ferroelectric pattern 833.

Referring to FIG. 47, a curing pattern 844, an upper electrode 843, a fifth insulating pattern 847, a word line 845, a sixth insulating pattern 846 and a wire 802 may be formed by processes substantially the same as those described above in connection with FIGS. 37-39. The wire 802 may be located in a fifth hole 848, and may include a lower portion 849 and an upper portion 850.

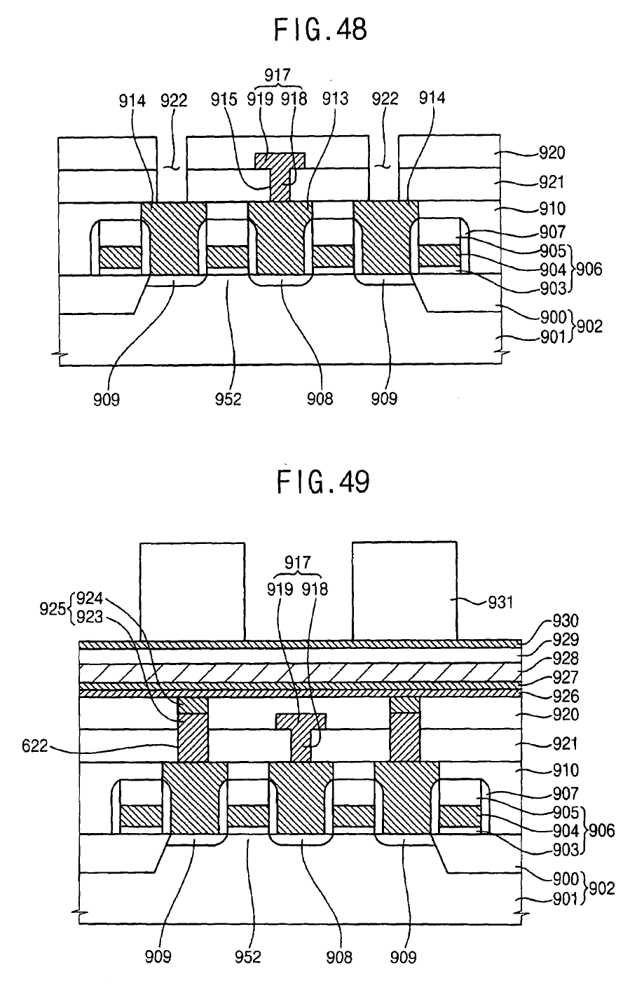

FIGS. 48-53 illustrate cross-sectional views of stages in a method of manufacturing a ferroelectric memory device in accordance with a tenth embodiment of the present invention. Referring to FIG. 48, a structure substantially the same as that illustrated in FIG. 31 may be formed by performing processes substantially the same as those described above in connection with FIGS. 30 and 31.

Referring to FIGS. 48 and 49, a third conductive layer (not shown) may be formed on a third insulating pattern 920 and may fill up a third hole 922. The third conductive layer may include, e.g., tungsten. A preliminary first contact (not shown) may be formed by planarizing the third conductive layer until the third insulating pattern 920 is exposed.

Where the preliminary first contact includes tungsten, dishing may occur at an upper portion of the preliminary first contact. Thus, a second contact 924 may be formed to prevent the dishing. In detail, an etch-back process may be performed on the preliminary first contact to remove an upper portion of the preliminary first contact. Thus, the preliminary first contact may be transformed into a first contact 923. The first contact 923 may partially fill the fourth hole 922. A fourth conductive layer (not shown) may be formed on the third insulating pattern 920 to fill up the fourth hole 922 that is partially filled with the first contact 923. The fourth conductive layer may include, e.g., tungsten nitride. The fourth conductive layer may be planarized until the third insulating pattern 920 is exposed. Thus, a second contact 924 filling up the hole that is partially filled with the first contact 923 may be formed. As a result, a contact structure 925 including the first contact 923 and the second contact 924 may be formed in the fourth hole 922.

A first adhesion layer 926 may be formed on the third insulating pattern 920 and the contact structure 925. The first adhesion layer 926 may include, e.g., titanium. An oxidation preventing layer 927 may be formed on the first adhesion layer 926. The oxidation preventing layer 927 may include, e.g., titanium aluminum nitride.

A lower electrode layer 928 may be formed on the oxidation preventing layer 927. The lower electrode layer 928 may include a conductive material, e.g., metal, polysilicon doped with impurities, conductive metal nitride, etc.

A ferroelectric layer 929 may be formed on the lower electrode layer 928. The ferroelectric layer 929 may include a ferroelectric material including titanium and oxygen, e.g., one or more of PZT, SBT, BLT, PLZT, BST, etc.

In an implementation (not shown), a second adhesion layer including aluminum oxide may be formed on the ferroelectric layer 929, which may protect the ferroelectric layer 929. In addition, the second adhesion layer may firmly attach a mask pattern 931, which may be formed subsequently, to the ferroelectric layer 929.

In another implementation, a second adhesion layer 930 may be formed on the ferroelectric layer 929. The second adhesion layer 930 may include a metal oxide having a perovskite structure such as strontium ruthenium oxide or chromium ruthenium oxide. The second adhesion layer 930 may be formed using, e.g., a PVD process such as a sputtering process. When the second adhesion layer 930 including the metal oxide is formed by the PVD process, the process may not employ a source gas including hydrogen. Thus, a dead layer may not be formed at a surface of the ferroelectric layer 929.

The second adhesion layer 930 may firmly attach a mask pattern 931, which may be formed subsequently, to the ferroelectric layer 929. In addition, hydrogen may not reach the ferroelectric pattern 929 through the second adhesion layer 930 in subsequent processes where the second adhesion layer 930 includes the metal oxide having the perovskite structure.

A mask layer (not shown) may be formed on the second adhesion layer 930. The mask layer may include, e.g., oxide, nitride, oxynitride, etc. For example, the mask layer may include one or more of BPSG, PSG, USG, SOG, FOX, PE-TEOS, HDP-CVD oxide, silicon nitride, silicon oxynitride, etc. Where the mask layer is formed using PE-TEOS, the mask layer may be formed at a relatively low temperature, e.g., about 200° C. A photolithography process may be performed on the mask layer, thereby transforming the mask layer into the mask pattern 931.

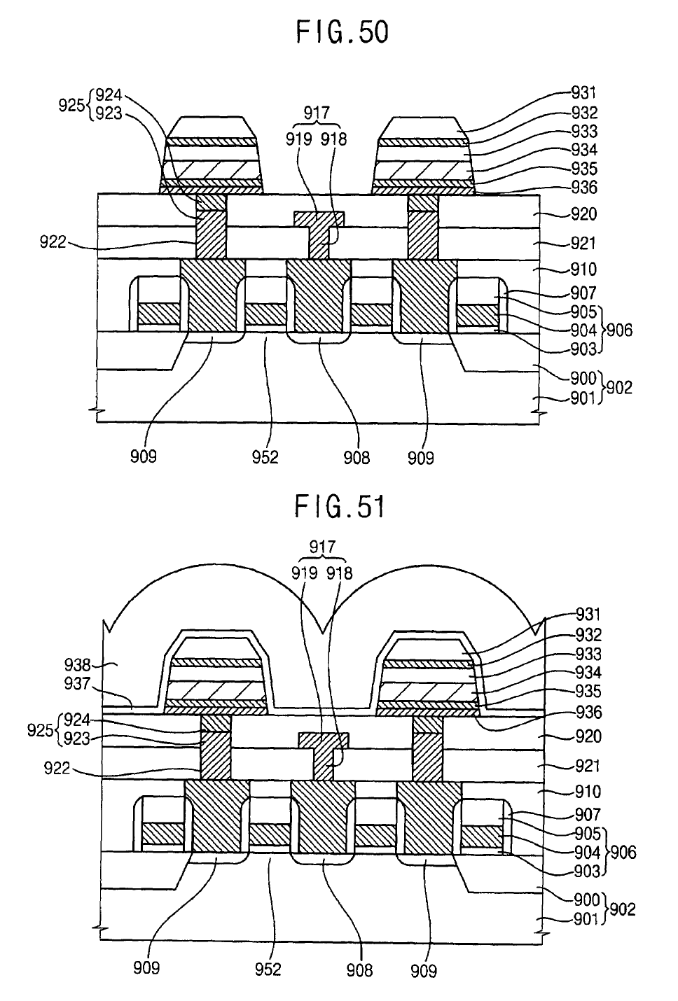

Referring to FIG. 50, the second adhesion layer 930, the ferroelectric layer 929, the lower electrode layer 928, the oxidation preventing layer 927 and the first adhesion layer 926 may be etched, e.g., using an anisotropic etch, using the mask pattern 931 as an etch mask. Thus, the second adhesion layer 930, the ferroelectric layer 929, the lower electrode 928, the oxidation preventing layer 927 and the first adhesion layer 926 may be transformed into a second adhesion pattern 932, a ferroelectric pattern 933, a lower electrode 934, an oxidation preventing pattern 935 and a first adhesion pattern 936, respectively. A size of the mask pattern 931 may be decreased during the etching of the second adhesion layer 930, the ferroelectric layer 929, the lower electrode layer 928, the oxidation preventing layer 927 and the first adhesion layer 926.

Referring to FIG. 51, a capping layer 937 covering the third insulating pattern 920, the mask pattern 931, the second adhesion pattern 932, the ferroelectric pattern 933, the lower electrode 934, the oxidation preventing pattern 935 and the first adhesion pattern 936 may be formed. The capping layer 937 may protect the ferroelectric pattern 933. For example, the capping layer 937 may prevent hydrogen from deteriorating the ferroelectric pattern 933.

A fourth insulating layer 938 may be formed on the capping layer 937. The fourth insulating layer 938 may include, e.g., oxide, nitride, oxynitride, etc. For example, the fourth insulating layer 938 may include one or more of BPSG, PSG, USG, SOG, FOX, PE-TEOS, HDP-CVD oxide, silicon nitride, silicon oxynitride, etc.

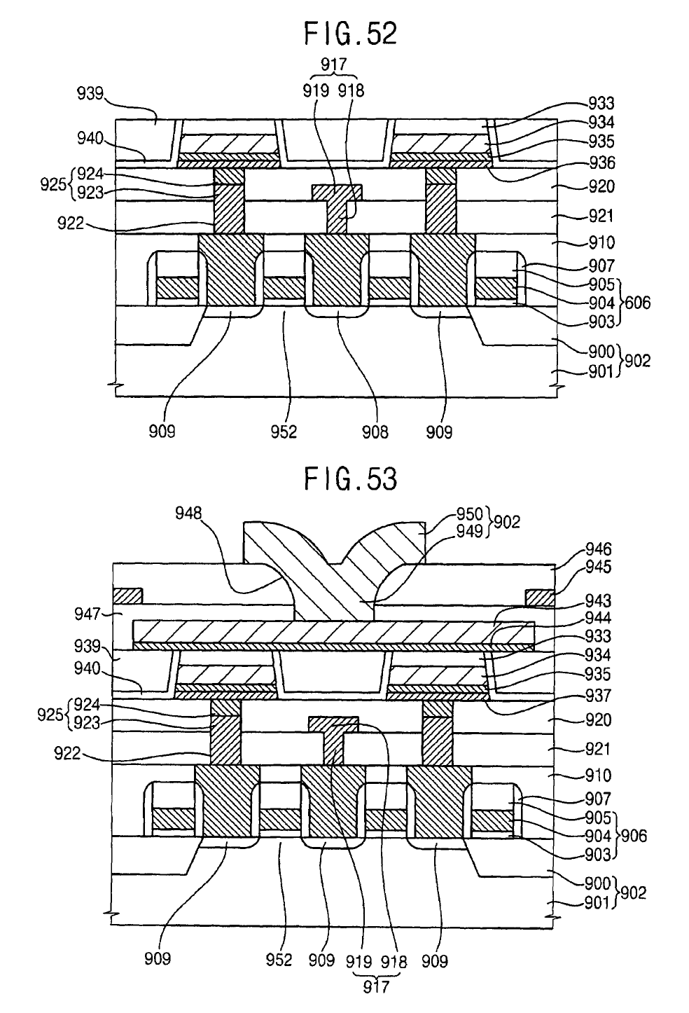

Referring to FIG. 52, a CMP process may be performed on the fourth insulating layer 938, the capping layer 937, the mask pattern 931 and the second adhesion pattern 932 until the ferroelectric pattern 933 is exposed. Thus, the fourth insulating layer 938 and the capping layer 937 may be transformed into the fourth insulating pattern 939 and the capping pattern 940. The mask pattern 931 and the second adhesion pattern 932 may be removed by the CMP process.

A slurry including ceria may be used in the CMP process. When the slurry includes ceria, a polishing rate of the fourth insulating layer 938 may be greater than a polishing rate of the ferroelectric pattern 933 in the CMP process. Thus, the ferroelectric pattern 933 may be used as a polishing stop pattern in the CMP process.

A pH of the slurry may be about 5 to about 9. In an implementation, the pH of the slurry may be about 6 to about 8. Using a pH of less than about 5 may increase the polishing rate of the ferroelectric pattern 933. Using a pH of more than about 9 may also increase the polishing rate of the ferroelectric pattern 933. If the polishing rate of the ferroelectric pattern 933 in the slurry is unduly increased, it may not be effective to use the ferroelectric pattern 933 as a polishing stop pattern.

The second adhesion pattern 932 may be efficiently removed by the CMP process because a polishing rate of the second adhesion pattern 932 including the metal oxide such as strontium ruthenium oxide or chromium ruthenium oxide may be relatively large in the CMP process.

Referring to FIG. 53, a curing pattern 944, an upper electrode 943, a fifth insulating pattern 947, a word line 945, a sixth insulating pattern 946 and a wire 902 may be formed by processes substantially the same as those described above in connection with FIGS. 37-39. The wire 902 may be located in a fifth hole 948, and may include a lower portion 949 and an upper portion 950.

### Polishing Experiment

A ferroelectric layer including PZT was prepared. First to sixth slurries were prepared. The first to third slurries included ceria as an abrasive, whereas the fourth to sixth slurries included silica as an abrasive. The first to sixth slurries had pHs of about 2.4, about 7.7, about 11.5, about 2.3, about 7.5 and about 11, respectively.

CMP processes were performed on representative ferroelectric layers using the first to sixth slurries, respectively, and the polishing rates of the ferroelectric layer were measured. Table 1 shows results from this polishing experiment.

TABLE 1

| | First | Second | Third | Fourth | Fifth | Sixth |
|---|---|---|---|---|---|---|
| | Slurry | Slurry | Slurry | Slurry | Surry | Slurry |
| Abrasive | Ceria | Ceria | Ceria | Silica | Silica | Silica |
| pH | 2.4 | 7.7 | 11.5 | 2.3 | 7.5 | 11 |
| Polishing Rate | 96 | 22 | 76 | 302 | 89 | 191 |
| (Å/min) | | | | | | |

As shown in Table 1, when the CMP process was performed using the second slurry, the polishing rate of the ferroelectric layer was relatively low. The second slurry may be particularly suitable for chemical mechanical polishing of a structure including a ferroelectric pattern that is formed by etching a ferroelectric layer, wherein the ferroelectric pattern is used as a polishing stop layer.

### Experiment Regarding Polarization of a Ferroelectric Pattern

Ferroelectric patterns including PZT were prepared. A slurry was prepared, the slurry including ceria as an abrasive and having a pH of about 7.7.

Using the slurry, CMP processes were performed on the ferroelectric patterns for about 15 seconds, about 45 seconds and about 75 seconds, independently. Thereafter, polarizations of the ferroelectric patterns with respect to voltages applied to the ferroelectric patterns were measured. In addition, leakage currents flowing through the ferroelectric patterns were measured.

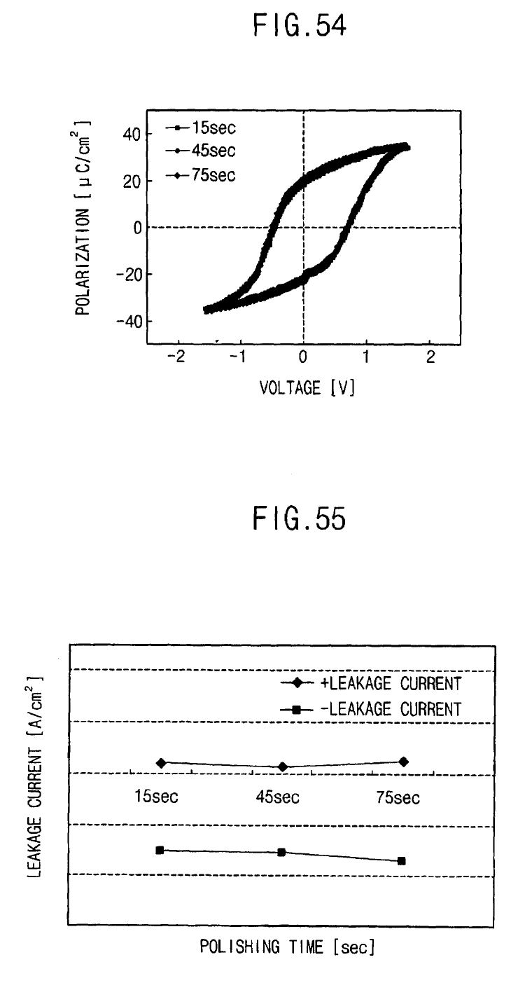

FIG. 54 illustrates a graph of hysteresis loops of ferroelectric patterns measured in the experiment regarding the polarization of the ferroelectric patterns. Referring to FIG. 54, hysteresis loops for each of the 15 second, 45 second and 75 second CMP processes substantially overlap, indicating that the hysteresis loops were not substantially altered even when increasing a time over which the CMP process was performed. Thus, the CMP process performed on the ferroelectric pattern using the slurry may not deteriorate characteristics of the ferroelectric pattern.

FIG. 55 illustrates a graph of leakage currents flowing through ferroelectric patterns measured in an experiment concerning a polarization of the ferroelectric patterns. Referring to FIG. 55, the leakage currents were substantially constant even when increasing a time over which the CMP process was performed. Thus, the CMP process performed on the ferroelectric pattern using the slurry may not deteriorate characteristics of the ferroelectric pattern.

### Experiment Regarding an Etch-Back Process

Ferroelectric patterns including PZT were prepared. First to fifth etching gases were prepared. The first to fifth etching gases included carbon tetrafluoride (CF₄), chlorine (Cl₂), oxygen (O₂), hydrogen bromide (HBr) and argon (Ar), respectively. Etch-back processes were performed on the ferroelectric patterns using the first to fifth etching gases. Polarizations of the ferroelectric patterns were then measured.

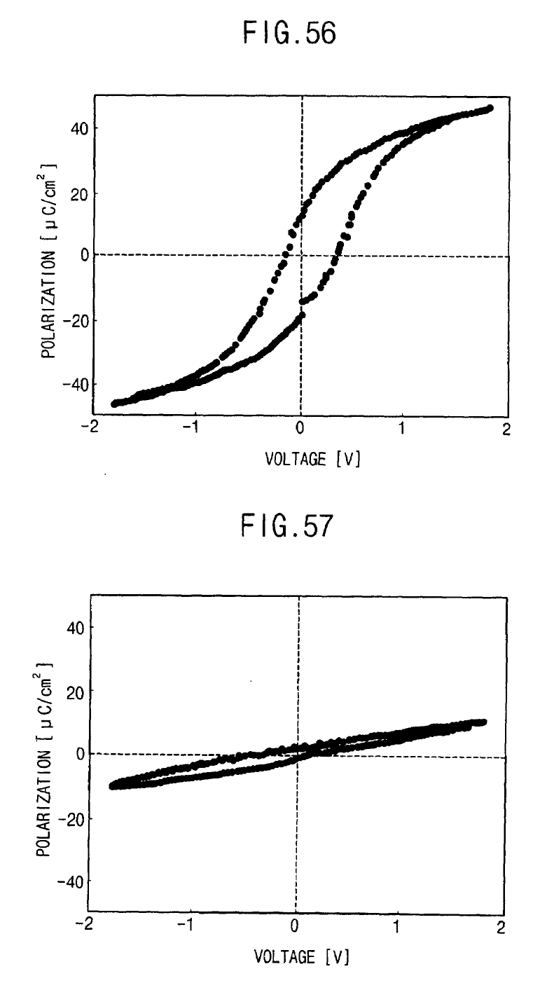

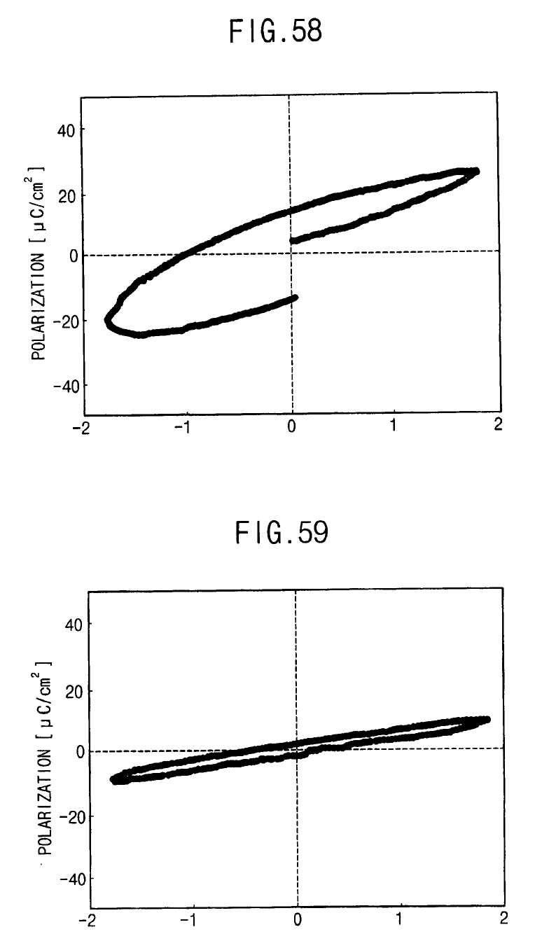

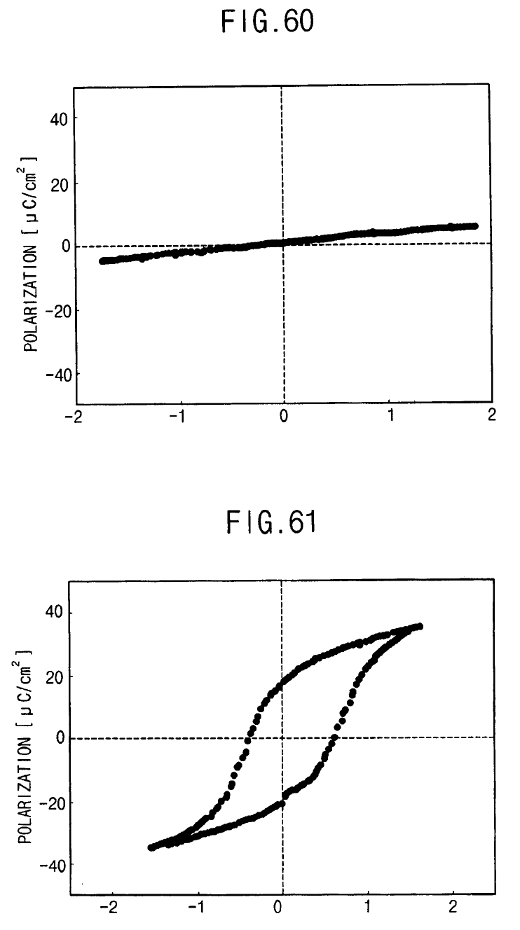

FIGS. 56-60 illustrate graphs of hysteresis loops of ferroelectric patterns measured in the experiment regarding the etch-back process. Referring to FIG. 56, when the etch-back process is performed on the ferroelectric pattern using the first etching gas including carbon tetrafluoride, the polarization of the ferroelectric pattern was satisfactory. Accordingly, when an etch-back process is performed using the first etching gas, the ferroelectric pattern may experience little or no damage.

Referring to FIGS. 57-60, when the etch-back processes were performed on the ferroelectric patterns using the second to fifth etching gases, the polarizations of the ferroelectric patterns were generally poor. Thus, the use of the second to fifth etching gasses in etch-back processes may be unsatisfactory, as the ferroelectric pattern may be damaged.

### Experiment Regarding a Second Adhesion Layer Including a Metal Oxide

A second adhesion layer was formed on a ferroelectric layer including PZT. The second adhesion layer included strontium ruthenium oxide having a perovskite structure. The second adhesion layer was formed by a sputtering process. A thickness of the second adhesion layer was about 100 Å.

A mask layer including PE-TEOS oxide was formed on the second adhesion layer. A thickness of the mask layer was about 2000 Å. A CMP process was performed on the mask layer and the second adhesion layer until the ferroelectric layer was exposed. A downward pressure was about 1.0 psi in the CMP process. A polishing table had a rotation speed of about 10 rpm. The CMP process was performed for about 60 seconds. A slurry used in the CMP process included ceria and had a pH of about 7.7.

FIG. 61 illustrates a graph of a hysteresis loop of a ferroelectric layer measured in the experiment regarding the second adhesion layer including a metal oxide. Referring to FIG. 61, the polarization of the ferroelectric layer was satisfactory, as a dead layer was not formed at a surface of the ferroelectric layer when the second adhesion layer was formed.

According to the present invention, a ferroelectric pattern may be efficiently used as a polishing stop pattern in a CMP process. In addition, the ferroelectric pattern may not be deteriorated by the CMP process. Furthermore, a surface characteristic of the ferroelectric pattern may be improved by the CMP process.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a ferroelectric device, comprising:
forming a ferroelectric pattern on a substrate, the ferroelectric pattern including a ferroelectric material including titanium and oxygen;
forming an insulating layer on the ferroelectric pattern; and
planarizing the insulating layer using a slurry until the ferroelectric pattern is exposed, wherein the ferroelectric pattern serves as a polishing stop pattern and the slurry includes ceria.

2. The method as claimed in claim 1, wherein the ferroelectric material includes at least one of PZT, SBT, BLT, PLZT, or BST.

3. The method as claimed in claim 1, wherein the slurry has a pH of about 5 to about 9.

4. The method as claimed in claim 1, wherein the insulating layer includes at least one of boro-phosphor silicate glass, phosphor silicate glass, undoped silicate glass, spin-on-glass, flowable oxide, plasma-enhanced tetra-ethyl-ortho-silicate, high density plasma chemical vapor deposition oxide, silicon nitride, or silicon oxynitride.

5. The method as claimed in claim 1, wherein planarizing the insulating layer includes a chemical mechanical polishing process.

6. The method as claimed in claim 1, further comprising:
forming a lower electrode on the substrate, wherein the lower electrode is between the substrate and the ferroelectric pattern; and
forming an upper electrode on the ferroelectric pattern.

7. The method as claimed in claim 6, wherein:
the insulating layer covers the ferroelectric pattern,
exposing the ferroelectric pattern transforms the insulating layer into an insulating pattern, and
the upper electrode is formed on the ferroelectric pattern and the insulating pattern.

8. The method as claimed in claim 6, further comprising forming a transistor on the substrate, wherein the lower electrode is electrically connected to a source/drain region of the transistor.

9. The method as claimed in claim 6, further comprising:
forming a curing pattern on the substrate, wherein the curing pattern is between the ferroelectric pattern and the upper electrode, and
the curing pattern includes strontium ruthenium oxide.

10. The method as claimed in claim 1, further comprising:
forming a lower electrode layer on the substrate;
forming a ferroelectric layer on the lower electrode layer;
forming an adhesion layer on the ferroelectric layer;
forming a mask pattern on the adhesion layer; and
etching the adhesion layer, the ferroelectric layer and the lower electrode layer using the mask pattern as an etch mask so as to form an adhesion pattern, the ferroelectric pattern and a lower electrode.

11. The method as claimed in claim 10, wherein planarizing the insulating layer includes planarizing the mask pattern and the adhesion pattern using the slurry.

12. The method as claimed in claim 11, further comprising forming an upper electrode on the ferroelectric pattern after planarizing the mask pattern, the adhesion pattern and the insulating layer.

13. The method as claimed in claim 10, wherein:
forming the adhesion layer includes forming an oxide using a source gas that contains hydrogen, and
the hydrogen deteriorates a surface of the ferroelectric layer.

14. The method as claimed in claim 13, wherein the oxide is an aluminum oxide.

15. The method as claimed in claim 14, wherein the hydrogen contained in the source gas is provided by trimethylaluminum.

16. The method as claimed in claim 13, further comprising removing the deteriorated surface after planarizing the insulating layer.

17. The method as claimed in claim 16, wherein removing the deteriorated surface includes a chemical mechanical polishing process using a slurry that includes ceria.

18. The method as claimed in claim 17, wherein the slurry used in removing the deteriorated surface has a pH of about 5 to about 9.

19. The method as claimed in claim 16, wherein removing the deteriorated surface includes a chemical mechanical polishing process using a slurry that includes silica.

20. The method as claimed in claim 16, wherein removing the deteriorated surface includes an etch-back process using an etching gas that includes fluorine.

21. The method as claimed in claim 10, wherein the adhesion layer includes a metal oxide having a perovskite structure.

22. The method as claimed in claim 21, wherein the metal oxide is strontium ruthenium oxide or chromium ruthenium oxide.

23. The method as claimed in claim 10, wherein the adhesion layer is formed without using a source gas that includes hydrogen.

24. The method as claimed in claim 23, wherein the adhesion layer is formed by a physical vapor deposition process.
